(19) United States
(12) Patent Application Publication
(10) Pub. No.: US 2003/0025618 A1
(43) Pub. Date: Feb. 6, 2003

(54) Method of using twelve sensors to produce data

(76) Inventor: James W. Burrell IV, Union, NJ (US)

Correspondence Address: EZRA SUTTON, P.A., A PROFESSIONAL CORPORATION, PLAZA 9, 900 ROUTE 9, WOODBRIDGE, NJ, 07095, US

(21) Appl. No.: 09/910,323

(22) Filed: Jul. 20, 2001

(51) Int. Cl. H03K 17/94; H03M 11/00

(52) U.S. Cl. 341/23; 379/368

(57) ABSTRACT

This invention relates to a novel and logical way of using twelve sensors for data representation or data entry coding. This invention also relates to a method of producing alphanumeric data using short duration or long duration twelve sensor activation, simultaneous activation and/or sequential activation. Activating one of the ten numbered sensors produces numbers. Activating a first left sensor of a second set of three sensors exits the number mode and enters a data character mode. Activating a third right sensor of a second set of three sensors exits the data character mode and re-enters the number mode. The twelve sensor set enters a shiftable data character mode when a first left sensor of the second set of three sensors is activated two or three times. Activating a sensor of a first set of nine sensors in a data character mode produces a data character. Activating a sensor of a first set of nine sensors combined with the activation of a sensor of a second set of three sensors in a data character mode also produces a data character, and secondary activation of the second sensor used produces an upper-case data character in a shiftable data character mode. Activating a first left sensor of a second set of three sensors, in a data character mode, combined with the activation of a third right sensor of a second set of three sensors once, twice or three times enters a punctuation mode. This method of data entry produces numbers, all lower-case data, all upper-case data, a space, all punctuation, symbols and control found on a standard keyboard.

### FIELD OF THE INVENTION

This invention relates to a novel and logical way of using nine sensors combined with three sensors for data character representation and/or data entry. This invention also relates to a method of producing alphanumeric data using short duration or long duration twelve sensor activation, simultaneous activation and/or sequential activation. This invention would be properly classified in the U.S. patent classification system under:

CLASS 379 TELEPHONIC COMMUNICATIONS and subclasses;

/52 INCLUDING AID FOR HANDICAPPED USER (E.G., VISUAL, TACTILE, HEARING AID COUPLING),

/56 HAVING ELECTROMAGNETIC LINK FOR SPEECH OR PAGING SIGNAL. (E.G., LIGHT WAVE LINK),

/57 .Control of selectively responsive paging arrangement over telephone line,

/58 .Radio telephone system or instrument,

/59 ..Zoned or cellular system,

/61 ..Including cordless extension set (i.e., having single subscriber line access),

/63 ..Including supervisory or control signaling,

/90 TELEPHONE LINE OR SYSTEM COMBINED WITH DIVERSE ELECTRICAL SYSTEM OR SIGNALING (E.G., COMPOSITE),

/93 .With transmission of digital message signal over a telephone line,

/97 ..By voice frequency signal (e.g., tone code),

/98 ...By modulated audio tone,

/100 .To produce visual-graphic copy reproduction (e.g.,facsimile),

/105 ..From terminal,

/108 .Telegraphy,

/109 ..Over telephone line,

/350 SUPERVISORY OR CONTROL LINE SIGNALING,

/372 .Signal reception at substation,

/419 TERMINAL,

/428 .Housing or housing component,

/434 ..Specified terminal configuration (e.g., novelty type).

The code part of this invention belongs in:

CLASS 341 CODED DATA GENERATION OR CONVERSION and sub-classes;

/1 DIGITAL PATTER READING TYPE CONVERTER,

/3 .Plural types of codes on a single carrier,

/9 .Having combined (e.g., denominational, combinational code) coding pattern,

/17 .Actuated by physical projection,

/20 BODILY ACTUATED CODE GENERATOR,

/21 .For handicapped user,

/22 .Including keyboard or keypad,

/23 ..Variable key legends,

/30 ..For numerical pulse type transmission,

/34 .Pressure sensitive actuation,

/50 DIGITAL CODE TO DIGITAL CODE CONVERTERS,

/56 .To or from multi-level codes,

/57 ..Binary to or from ternary,

/64 .To or from number or pulses,

/67 .To or from variable length codes,

/82 .To or from mixed code formats,

/90 .To or from alphanumeric code formats,

/106 .Coding from table look-up techniques.

This invention also belongs in:

CLASS 364 ELECTRICAL COMPUTERS AND DATA PROCESSING SYSTEMS and sub-classes;

/130 DATA PROCESSING CONTROL SYSTEMS, METHODS OR APPARATUS,

/140 .Sequential or selective,

/1141 ..State of condition or parameter (e.g., on/off),

/1142 ...Position responsive,

/180 .Multiple modes (e.g., digital/analog),

/188 .With operator control interface (e.g., control/display console),

/189 ..Keyboard,

/221 .Control systems,

/221.6 ..Multiple mode,

/222.2 .Communication/data transmission,

/222.3 ..Telephone exchange,

OPERATIONAL CONTROL

/260 .Data transfer,

/260.1 ..external,

/262.4 .Instructional sequence,

/262.9 ..Other specific instruction sequence operation,

/400 APPLICATIONS,

/1419.1 .Word processing,

/419.14 ..Replacement for characters or words,

/419.16 ..Multilingual,

/419.17 ..Editing (i.e., deletion, insertion, blocking, hyphenation, punctuation or footnotes),

/514 R .Communication engineering,

/600 ELECTRIC HYBRID COMPUTER,

/602 .Specialized function performed,

/605 ..Integration or differentiation,

/700 ELECTRICAL DIGITAL CALCULATING COMPUTER,

/705.01 .Combined with diverse art device,

/705.05 ..Communication device (e.g., telephone, radio, television),

/709.01 .With specialized input,

/709.08 ..Flexible input,

/709.12 ..Including specific keyboard type information entry,

/1709.16 ...Key sequencing (i.e., sequence defines function),

/710.01 .With specialized output,

/710.08 ..Selective output,

/710.09 ..Sequential output,

/710.1 ..Using particular format,

APPLICATIONS

/916.2 ..Learning/trainable,

/919 .Communications/data transmission system,

/919.4 ..Telephone,

/919.5 ..Other specific communications application,

GENERIC DEVICE

/926 .Analog input/output,

/926.7 ..Character generator,

/933.9 .Terminal.

### BACKGROUND OF THE INVENTION

This patent application is an improvement on the invention found in U.S. Pat. No. 6,043,761 to Burrell, IV, U.S. Pat. No. 6,184,803 B1 to Burrell, IV and U.S. Pat. No. 6,232,892 to Burrell, IV. The alphabetic code shown in FIGS. 2A through 2C of the prior art, was invented in August of 1972. In November of 1972, the inventor went on a school field trip to Princeton. Mr. Burrell sat and talked with ex-New Jersey governor Thomas Kean's grandmother, Mary Alice Kean, the entire way to Princeton. Mrs. Kean invited the young Mr. Burrell to join her for her meeting with the developers of today's Internet. One of the Internet developers explained the project they were working on. Mr. Burrell briefly explained the invention he was working on, which allowed for the entry of alphanumeric data through the standard twelve key telephone keypad. One of the developers said that they were looking at the Flanagan invention and a means of assigning alphanumeric data strings to addresses, instead of the numbers and decimal points which were being used. They were contemplating on the use of the hyphen instead of the space, only because you can see it and it was already being used in telephone numbers. Mr. Burrell argued for the use of the space, because the space occurs the most often in normal communication and language, but then agreed to the hyphen because you can see it. Mr. Burrell then modified the invention he was working on to use the hyphen/dash/minus sign, which can be found in this patent application.

### DESCRIPTION OF THE PRIOR ART

The twelve sensor touch-tone telephone keypad arrangement and twelve pairs of tones, dual tone multifrequency signal (DTMF), produced by independently depressing any one of the twelve sensors have become the standard throughout the world. Since the advent of the twelve key push-button telephone arrangement, many have tried to produce alphanumeric text and control means using only twelve sensors. In the telephony industry, the twelve sensor (four high/three wide) push-button telephone keypad arrangement with twenty-four letters of the alphabet, excluding the “Q” and “Z”, arranged in groups of threes, located on the faces of the sensors numbered two “2” through nine “9” has become the world standard. In the past, the “Q” and “Z” have been located on the face of the sensors in a few different locations. The most common way in the past, is where the “Q” and “Z” are located on the “1” sensor. Usually the “Q” and “Z” are located next to each other above the “1” or the “Q” on the “7” sensor and the “Z” on the “9” sensor.

Apparatuses, systems and methods of possible relevance include the following prior art:

Witten, I. H., “Principles of Computer Speech”

U.S. Pat. No. 2,073,333 to Chireix

U.S. Pat. No. 3,381,276 to James

U.S. Pat. No. 3,526,892 to Bartlett et al.

U.S. Pat. No. 3,573,376 to Bartlett et al.

U.S. Pat. No. 3,582,554 to LeBlang

U.S. Pat. No. 3,618,038 to Stein

U.S. Pat. No. 3,647,973 to James et al.

U.S. Pat. No. 3,675,513 to James Flanagan, et al.

U.S. Pat. No. 3,746,793 to Sachs

U.S. Pat. No. 3,778,553 to Rackman

U.S. Pat. No. 3,833,765 to Hilborn et al.

U.S. Pat. No. 3,870,821 to Steury

U.S. Pat. No. 3,879,722 to Knowlton

U.S. Pat. No. 3,967,273 to Knowlton

U.S. Pat. No. 4,012,599 to Jerome Meyer

U.S. Pat. No. 4,005,388 to Morley et al.

U.S. Pat. No. 4,007,443 to Bromberg et al.

U.S. Pat. No. 4,191,854 to Coles

U.S. Pat. No. 4,304,968 to Klausner et al.

U.S. Pat. No. 4,307,266 to Messina

U.S. Pat. No. 4,344,069 to Prame

U.S. Pat. No. 4,381,502 to Prame

U.S. Pat. No. 4,426,555 to Underkoffler

U.S. Pat. No. 4,427,848 to Peter Tsakanikas

U.S. Pat. No. 4,440,977 to John Pao, et al.

U.S. Pat. No. 4,481,508 to Kamei et al.

U.S. Pat. No. 4,486,741 to Nozawa et al.

U.S. Pat. No. 4,500,751 to Darland et al.

U.S. Pat. No. 4,532,378 to Yasunoba Nakayama, et al.

U.S. Pat. No. 4,585,908 to Louis Smith

U.S. Pat. No. 4,608,457 to Fowler et al.

U.S. Pat. No. 4,649,563 to Risken

U.S. Pat. No. 4,650,927 to Leland James

U.S. Pat. No. 4,658,417 to Hashimoto et al.

U.S. Pat. No. 4,674,112 to George Kondraske, et al.

U.S. Pat. No. 4,677,659 to Dargan

U.S. Pat. No. 4,680,278 to Davis,II et al.

U.S. Pat. No. 4,724,423 to Kinoshita

U.S. Pat. No. 4,737,980 to William Curtin, et al.

U.S. Pat. No. 4,799,254 to Dayton et al.

U.S. Pat. No. 4,817,129 to Risken

U.S. Pat. No. 4,825,464 to Wen

U.S. Pat. No. 4,860,234 to Lapeyre

U.S. Pat. No. 4,891,777 to Lapeyre

U.S. Pat. No. 4,910,697 to Lapeyre

U.S. Pat. No. 4,918,721 to Kazuo Hashimoto

U.S. Pat. No. 4,924,431 to Lapeyre

U.S. Pat. No. 4,988,997 to Prame

U.S. Pat. No. 4,999,795 to Lapeyre

U.S. Pat. No. 5,007,008 to Beers

U.S. Pat. No. 5,031,119 to Dulaney et al.

U.S. Pat. No. 5,062,070 to Lapeyre

U.S. Pat. No. 5,067,103 to Lapeyre

U.S. Pat. No. 5,105,375 to Lapeyre

U.S. Pat. No. 5,117,455 to Danish

U.S. Pat. No. 5,124,940 to Lapeyre

U.S. Pat. No. 5,163,084 to Kim et al.

U.S. Pat. No. 5,184,315 to Lapeyre

U.S. Pat. No. 5,274,693 to Waldman

U.S. Pat. No. 5,303,288 to Duffy et al.

U.S. Pat. No. 5,339,358 to Danish et al.

U.S. Pat. No. 5,392,338 to Adel Danish, et al.

U.S. Pat. No. 5,486,823 to Tsai

U.S. Pat. No. 5,548,634 to Gahang et al.

U.S. Pat. No. 5,559,512 to Jasinski et al.

U.S. Pat. No. 5,581,593 to Engelke et al.

U.S. Pat. No. 6,043,761 to Burrell, IV

U.S. Pat. No. 6,184,803 to Burrell, IV

U.S. Pat. No. 6,232,892 to Burrell, IV

U.S. Pat. No. 3,675,513 to James Flanagan, et al. discloses a communication system for exchanging alphanumeric information. Flanagan produces numbers in the standard number mode by single key actuations. Actuating the asterisk “*” three times enters an alphabetic mode. In the alphabetic mode, the numbered alphabet key is actuated: once for the first left data character followed by the middle “0” key, twice for the second middle data character followed by the middle “0” key or three times for the third right data character followed by middle “0” key. The “Q”, “Z” and period “.” are located on the “1” key. The “Q” is produced by actuating the “1” key, followed by the actuation of the “0” key. The “Z” is produced by actuating the “1” key twice, followed by the actuation of the “0” key. The period “.” is produced by actuating the “1” key three times, followed by the actuation of the “0” key. The apparatus exits the alphabetic mode and re-enters the numeric mode by actuating the pound “#” key three times. The space is produced by actuating the pound “#” key followed by the “0” key. The enter/return function is produced by actuating the asterisk “*” key followed by the “0” key.

U.S. Pat. No. 3,967,273 to Knowlton does not use a standard phone keypad arrangement. Up to nine possible data characters are produced by one binary key. Letter and numbers are arranged on the sideways phone keypad corresponding to the arrangement of a standard QWERTY keyboard layout. Knowlton uses a four key binary keyboard combined with a nine key binary keyboard to produce numbers. A second four key binary keyboard combined with a nine key binary keyboard to produce the twenty-six letters of the alphabet and three symbols. A seven key binary keyboard combined with a nine key binary keyboard to produce symbols and functions. One key dedicated for a space and one key dedicated for a backspace.

U.S. Pat. No. 4,012,599 to Jerome Meyer discloses a communicator and encoding scheme. Meyer produces numbers by successively depressing the pound “#” key three times to enter a number mode followed by the single key actuations of the desired number keys. Actuation of the asterisk “*” key re-enters the alphabet mode. Meyer uses a three key binary keyboard (labeled “*” “0” and “#”) combined with a nine key binary control keyboard (numbered: 1, 2, 3, 4, 5, 6, 7, 8 and 9) to produce twenty-six letters of an alphabet excluding a space. The period “.”, “Q” and “Z” are located on the one key. The period “.” is produced by actuating the asterisk “*” key, followed by the actuation of the “1” key. The “Q” is produced by actuating the “0” key, followed by the actuation of the “1” key. The “Z” is produced by actuating the pound “#” key, followed by the actuation of the “1” key. A space is produced by pausing after entering a word by inserting a period or by flashing the last letter through multiple actuations of the alphabetic key. Actuation of the asterisk “*” key three times exits the alphabet mode and enters a symbol mode. Moving from the number mode to the symbol mode requires actuation of the asterisk “*” key four times. Exiting the symbol mode requires actuation of the pound “#” key once.

Witten, I. H., “Principles of Computer Speech” produces numbers by depressing the pound “#” key twice to enter a number mode followed by the single key actuations of the desired number keys. Actuation of the asterisk “*” key twice enters the alphabetic mode followed by the single key actuations of the desired alphabetic data found on the numbered keys. Actuation of the pound “#” key at the end of the word ends the one key data string and sends it to be resolved by the computer. Eight percent of words are ambiguities. A nine key binary keyboard is used to produce twenty-six letters of an alphabet including a space. The space 37 ”, “Q” and “Z” are located on the one key. A space is produced after entering a word or by actuation of the “1” key. Actuation of the asterisk “*” key once followed by the actuation of the zero “0” key exits the alphabet mode and enters a symbol mode with three possible symbols on each key. “in a dictionary of 24,500 words, just under 200 ambiguities (8% of words) were discovered.”.

U.S. Pat. No. 4,585,908 to Louis Smith discloses a data entry and display circuit. Smith produces numbers by successively depressing the desired numbered key two times. Smith uses a nine key binary keyboard combined with a three key binary keyboard to produce twenty-six letters of the alphabet excluding a space. Numbers require double actuation of the numeric key to produce a number. An unused data character labeled as a (blank) is positioned between the “Q” and “Z” on the one key. The “Q” is produced by actuating the “1” key, followed by the actuation of the pound “#” key. The unfilled data position between the “Q” and “Z”, referred to as “(blank)”, is not used for anything. The “Z” is produced by actuating the “1” key, followed by the actuation of the pound “#” key. A space is produced by successively depressing the pound “#” key followed by the “0” key. The backspace is produced by successively depressing the asterisk “*” key followed by the “0” key. The insertion of a character is produced by successively depressing the “0” key followed by the asterisk “*” key. The deletion of a character is produced by successively depressing the “0” key followed by the pound “#” key. The tab function is produced by successively depressing the asterisk “*” key followed by the pound “#” key. The return/enter function is produced by successively depressing the pound “#” key followed by the asterisk “*” key. Each data entry requires two successive actuations to produce numbers or letters. Smith claims a circuit requiring an actuation of a key for an unspecified predetermined duration, along with a second key actuation, with a second unspecified predetermined duration of actuation. Actuation of the asterisk “*” key does not exit a one key number mode and enter a two key alphabetic mode in and does not allow for any punctuation.

U.S. Pat. No. 4,608,457 to Fowler et al. produces numbers using two key combinations by actuating the desired number key followed by the pound “#” key. Fowler uses a 10 key binary keyboard combined with a one key binary keyboard for numbers; a 9 key binary keyboard (numbered: 2, 3, 4, 5, 6, 7, 8, 9 and 0) combined with a three key binary keyboard (numbered: 1, 2 and 3) to produce letters of the alphabet: where the “Q” and “Z” are located on the middle “0” key; and a 10 key binary keyboard (numbered 1, 2, 3, 4, 5, 6, 7, 8, 9 and 0) combined with a one key binary keyboard (numbered: 4) to produce symbols, which includes a space and a double space; and a 12 key binary keyboard combined with a 1 key binary keyboard (numbered: 0) to produce 12 words and expressions. The device uses two key combinations to produce numbers, letters, symbols and words or expressions.

U.S. Pat. No. 4,918,721 to Kazuo Hashimoto discloses a phone capable of producing upper-case and lower-case letters. Hashimoto produces numbers in the standard number mode by single key actuations. Hashimoto uses as a one key binary keyboard (labeled “#”) actuated one time for the left data character, two times for the middle data character or three times for the right data character combined with an eleven key binary keyboard (numbered 1, 2, 3, 4, 5, 6, 7, 8, 9, 0 and “*”) to produce one of twenty-six lower case letters or a space on keys 1 through 9 and produces a comma and a period on the “0” key. Actuating the asterisk “*” key after entering one of twenty-six letters produces an upper case letter. Hashimoto also uses a 10 key binary keyboard (numbered 1, 2, 3, 4, 5, 6, 7, 8, 9 and 0) combined with a two key binary keyboard (labeled “*” and “#”) to produce numbers, letters and a space. Hashimoto positions from left to right; the “Q”, “Z” and “space” on the number “1” key. Two methods of data entry are disclosed. In the first, the “Q” is produced by actuating the pound “#” key, followed by the actuation the “1” key. The “Z” is produced by actuating the pound “#” key twice, followed by the actuation of the “1” key. The “space” is produced by actuating the pound “#” key three times, followed by the actuation of the “1” key. In the second method of data entry, the “Q” is produced by actuating the “1” key twice, followed by the actuation of the pound “#” key. The “q” is produced by actuating the “1” key twice, followed by the actuation of the asterisk “*” key. The “Z” is produced by actuating the “1” key three times, followed by the actuation of the pound “#” key. The “z” is produced by actuating the “1” key three times, followed by the actuation of the asterisk “*” key. The space “ ” is produced by actuating the “1” key four times, followed by the actuation of the pound “#” key. The left data character is produced by actuating the desired number key twice followed by the asterisk “*” key for a lower-case letter of the pound “#” key for an upper case letter. The middle data character is produced by actuating the desired number key three times followed by the asterisk “*” key for a lower-case letter or the pound “#” key for an upper case letter. The right data character is produced by actuating the desired number key four times followed by the asterisk “*” key for a lower-case letter of the pound “#” key for an upper case letter. The space is produced by actuating the “1” key four times followed by actuating the pound “#” key. The backspace is produced by actuating the pound “#” key three times followed by actuating the asterisk “*” key. The enter/return key is produced by actuating the pound “#” key twice followed by actuating the asterisk “*” key.

U.S. Pat. No. 4,427,848 to Peter Tsakanikas discloses an alphanumeric data transmission system. Tsakanikas positions from left to right; the “Q”, “Z” and hyphen “-” on the “1” key, although there is no coding scheme to layout to figure out actuation combinations for data representation. Single actuation is used for the left data position, double actuation is used for the middle data position and triple actuation is used for the right data position to produce the desired alphabetic data.

U.S. Pat. No. 4,440,977 to John Pao, et al. discloses a sequential twelve key apparatus. Pao positions from left to right; the period “.”, “Q” and “Z” on the “1” key. The period “.” is produced by actuating the “1” key, followed by the actuation of the asterisk “*” key. The “Q” is produced by actuating the “1” key, followed by the actuation of the “0” key. The “Z” is produced by actuating the “1” key, followed by the actuation of the pound “#” key.

U.S. Pat. No. 4,532,378 to Yasunoba Nakayama, et al. discloses a telephone apparatus for alphanumeric data entry. Nakayama positions from left to right; the “Q”, “Z” and period “.” on the “1” key. Single key actuation for the left data position, double actuation for the middle data position and triple actuation for the right data position, followed by the actuation of the “0” key, to produce the desired alphabetic data.

U.S. Pat. No. 4,650,927 to Leland James discloses a processor-assisted system for communicating using a telephone. James positions from left to right; the “Q” and “Z” on the “1” key. The “Q” is produced by actuating the “1” key. The “Z” is produced by actuating the “1” key. When the alphabetic word is completed, the user actuates the asterisk “*” key as a space, which sends the alphabetic data word to a computer to decipher what the word is.

U.S. Pat. No. 4,674,112 to George Kondraske, et al. discloses a communication apparatus including a method of use. Kondraske positions from left to right; the “Q”, “Z” and apostrophe “'” on the “1” key. The “Q” is produced by actuating the “1” key. The “Z” is produced by actuating the “1” key. When the alphabetic word is completed, the user actuates the asterisk “*” key as a space, which sends the alphabetic data word to a computer to decipher what the word is.

U.S. Pat. No. 4,737,980 to William Curtin, et al. discloses a method and apparatus for inputting data into a computer. Curtin positions from left to right; the “Q”, “Z” and a box(?) on the “1” key. Three alphabetic letters and the number on the key face are all represented by the same key actuation. A predetermined probability algorithm guesses what type of data the user entered into the phone/computer terminal.

U.S. Pat. No. 5,392,338 to Adel Danish, et al. discloses a method for entering alphabetic characters into a telephone apparatus. Danish et al. represents from left to right; the “Q” and “Z” on the “1” key. The “Q” is produced by actuating the “1” key. The “Z” is produced by actuating the “1” key twice. Numbers must be entered individually, followed by the activation of the pound “#” key.

U.S. Pat. No. 3,647,973 to James et al., U.S. Pat. No. 4,005,388 to Morley et al., U.S. Pat. No. 4,007,443 to Bromberg et al., U.S. Pat. No. 4,191,854 to Coles, U.S. Pat. No. 4,307,266 to Messina, U.S. Pat. No. 4,426,555 to Underkoffler, U.S. Pat. No. 4,608,457 to Fowler et al., U.S. Pat. No. 4,825,464 to Wen, are additional prior art patents where the “Q” and “Z” are represented or located on the “0” key.

U.S. Pat. No. 3,526,892 to Bartlett et al., U.S. Pat. No. 3,573,376 to Bartlett et al., U.S. Pat. No. 3,618,038 to Stein, U.S. Pat. No. 3,746,793 to Sachs, U.S. Pat. No. 3,833,765 to Hillborn et al., U.S. Pat. No. 3,870,821 to Steury, U.S. Pat. No. 3,879,722 to Knowlton, U.S. Pat. No. 3,967,273 to Knowlton, U.S. Pat. No. 4,304,968 to Klausner et al., U.S. Pat. No. 4,344,069 to Prame, U.S. Pat. No. 4,381,502 to Prame, U.S. Pat. No. 4,500,751 to Darland et al., U.S. Pat. No. 4,649,563 to Risken, U.S. Pat. No. 4,658,417 to Hashimoto et al., U.S. Pat. No. 4,677,659 to Dargan, U.S. Pat. No. 4,817,129 to Risken, U.S. Pat. No. 4,988,997 to Prame, U.S. Pat. No. 5,117,455 to Danish, U.S. Pat. No. 5,163,084 to Kim et al., U.S. Pat. No. 5,303,288 to Duffy et al., U.S. Pat. No. 5,339,358 to Danish et al., U.S. Pat. No. 5,486,823 to Tsai, U.S. Pat. No. 5,548,634 to Gahang et al., U.S. Pat. No. 5,559,512 to Jasinski et al., U.S. Pat. No. 6,043,761 to Burrell, IV, U.S. Pat. No. 6,184,803 B1 to Burrell, IV and U.S. Pat. No. 6,232,892 to Burrell, IV disclose prior art patents that use the phone keypad to enter alphanumeric data.

U.S. Pat. No. 2,073,333 to Chireix, U.S. Pat. No. 3,381,276 to James, U.S. Pat. No. 3,582,554 to LeBlang, U.S. Pat. No. 3,778,553 to Rackman, U.S. Pat. No. 4,481,508 to Kamei et al., U.S. Pat. No. 4,486,741 to Nozawa et al., U.S. Pat. No. 4,680,278 to Davis,II et al., U.S. Pat. No. 4,724,423 to Kinoshita, U.S. Pat. No. 4,799,254 to Dayton et al., U.S. Pat. No. 4,860,234 to Lapeyre, U.S. Pat. No. 4,891,777 to Lapeyre, U.S. Pat. No. 4,910,697 to Lapeyre, U.S. Pat. No. 4,924,431 to Lapeyre, U.S. Pat. No. 4,999,795 to Lapeyre, U.S. Pat. No. 5,007,008 to Beers, U.S. Pat. No. 5,031,119 to Dulaney et al., U.S. Pat. No. 5,062,070 to Lapeyre, U.S. Pat. No. 5,067,103 to Lapeyre, U.S. Pat. No. 5,105,375 to Lapeyre, U.S. Pat. No. 5,124,940 to Lapeyre, U.S. Pat. No. 5,184,315 to Lapeyre, U.S. Pat. No. 5,274,693 to Waldman, U.S. Pat. No. 5,581,593 to Engelke et al., disclose other prior art patents.

### Prior Art Comparison of Sensor Activations

U.S. Pat. No. 3,675,513 to James Flanagan, et al.

U.S. Pat. No. 3,879,722 to Knowlton

U.S. Pat. No. 4,012,599 to Jerome Meyer

Witten, I. H., “Principles of Computer Speech”

U.S. Pat. No. 4,585,908 to Louis Smith

U.S. Pat. No. 4,608,457 to Fowler, et al.

U.S. Pat. No. 4,918,721 to Kazuo Hashimoto

| | | 2A-2C | 5A-5C | 6A-6E | flanaga | knowlt | meyer | witten | smith | fowler | hashim |
|---|---|---|---|---|---|---|---|---|---|---|---|
| 3914 | a-z | 0 | 0 | 7828 | | 7828 | | | | | 12284 |
| 87 | A-Z | 8002 | 8002 | 261 | 12284 | 261 | 8002 | 4001 | 8002 | 8002 | 564 |
| 797 | space | 1594 | 1594 | 1594 | 1594 | 797 | | | 1594 | 1594 | 3188 |
| 33 | period | 66 | 66 | 66 | 132 | 66 | 66 | 165 | | 66 | 132 |
| 68 | comma | 204 | 204 | 204 | | 136 | 340 | 340 | | 136 | 204 |
| 18 | colon | 48 | 48 | 48 | | 32 | 80 | 80 | | 32 | |
| 6 | semi | 18 | 18 | 18 | | 12 | | 30 | | 12 | |
| 33 | enter | 99 | 99 | 99 | 66 | 66 | | 66 | 66 | | 99 |
| 31 | tab | | 93 | 93 | | 62 | | | 62 | | |
| 53 | 1-9 & 0 | 53 | 53 | 53 | 53 | 106 | 53 | 53 | 106 | 106 | 53 |
| | word# | | | | | | 674 | 797 | | | |
| | SHIFT | | | YES | | YES | | | | | YES |
| modes | 32 num | 32 | 64 | 64 | 96 | | 96 | 64 | | | |
| modes | 34 alph | 34 | 34 | 68 | 102 | | 34 | 68 | | | |
| 5038 | TOTAL | 10150 | 10275 | 10396 | 14327 | 9366 | 9345 | 5664 | 9830 | 9948 | 16524 |

| | | | | | | | | | | |
|---|---|---|---|---|---|---|---|---|---|---|
| # of taps | 2.01 | 2.03 | 2.06 | 2.84 | 1.86 | 1.85 | 1.12 | 1.95 | 1.97 | 3.27 |

### Comparison of Improved Sensor Activation

| | | 14A-B | 16A-C | 20A-F | flanaga | knowlt | meyer | smith | fowler | 15A-B | 17A-C |
|---|---|---|---|---|---|---|---|---|---|---|---|
| 3914 | a-z | | 6608 | 7828 | | 7828 | | | | | 5531 |
| 87 | A-Z | 6776 | 255 | 261 | 12284 | 261 | 8002 | 8002 | 8002 | 5663 | 261 |
| 797 | space | 797 | 797 | 1594 | 1594 | 797 | | 1594 | 1594 | 797 | 797 |
| 33 | period | 66 | 66 | 66 | 132 | 66 | 66 | | 66 | 66 | 66 |
| 68 | comma | 204 | 204 | 204 | | 136 | 340 | | 136 | 204 | 204 |
| 16 | colon | 48 | 48 | 48 | | 32 | 80 | | 32 | 48 | 48 |
| 6 | semi | 18 | 18 | 18 | | 12 | | | 12 | 18 | 18 |
| 33 | enter | 66 | 66 | 66 | 66 | 66 | | 66 | | 66 | 66 |
| 31 | tab | 93 | 93 | 93 | | 62 | | 62 | | 93 | 93 |
| 53 | 1-9 & 0 | 53 | 53 | 53 | 53 | 106 | 53 | 106 | 106 | 53 | 53 |
| | word# | | | | | | 674 | | | | |
| | SHIFT | | | YES | | YES | | | | | |
| modes | 32 num | 32 | 64 | 64 | 96 | | 96 | | | 32 | 64 |
| modes | 34 alph | 34 | 68 | 102 | 102 | | 34 | | | 34 | 68 |
| 5038 | TOTAL | 8187 | 8340 | 10430 | 14327 | 9366 | 9345 | 9830 | 9948 | 7074 | 7269 |

| | | | | | | | | | | |
|---|---|---|---|---|---|---|---|---|---|---|
| # of taps | 1.62 | 1.65 | 2.07 | 2.84 | 1.86 | 1.85 | 1.95 | 1.97 | 1.40 | 1.44 |

With the advent of the of the Teletypewriter (TTY), Telecommunication Device for the Deaf (TDD), Alphanumeric Pager, Text Messaging, the Wireless Web, 3^{rd} Generation Phone, the emerging 4^{th} Generation Phone, the Telephonic Internet and the transference of alphanumeric data over copper, fiber, light or wireless, requires an improvement in the efficiency of data entry using the phone. This invention is an improvement over all existing prior art using twelve sensors for alphanumeric data entry, simultaneous and/or sequential.

### SUMMARY OF THE INVENTION

This invention uses any standard twelve sensor phone keypad arrangement or twelve sensors to produce data, including numbers, lower-case letters, upper-case letters, a space, punctuation, symbols and control. The difference in the present invention is the keyboard arrangement and the method of producing data characters, such as Chinese or Japanese, using a twelve sensor arrangement. A preferred embodiment, has the letters “Q” and “Z” on the preferred number “1” or “9” sensor, with a “space” or a dash/hyphen/minus sign positioned between the “Q” and “Z”, the “ABC” on the preferred “2” or “1” sensor, the “DEF” on the preferred “3” or “2” sensor, the “GHI” on the preferred “4” or “3” sensor, the “JKL” on the preferred “5” or “4” sensor, the “MNO” on the preferred “6” or “5” sensor, the “PRS” on the preferred “7” or “6” sensor, the “TUV” on the preferred “8” or “7” sensor and the “WXY” on the “9” or “8” sensor. The “ABC” can be on the “2” sensor, “1” sensor or on any other sensor, as long as twenty-seven data characters are produced in a data character mode using nine sensors numbered one “1” through nine “9”, and a second set of three sensors; a first left sensor, a second middle sensor labeled zero “0” and a third right sensor. This invention also relates to a method of producing data using independent sensor activation, short duration or long duration sensor activation, simultaneous sensor activation and/or sequential sensor activation.

Activation of ten numbered sensors produces numbers in a number mode. Activation of a first left sensor of a second set of three sensors enters a data character mode. Activating a sensor of a first set of nine sensors in a data character mode produces a data character. The first set of nine sensors exits the data character mode and re-enters the ten sensor number mode when the third right sensor of the second set of three sensors is activated.

The twelve sensor set in the number mode produces a dot/period/decimal point when the first left sensor of the second set of three sensors is activated and combined with the activation of the second middle sensor of the second set of three sensors. The twelve sensor set in the number mode produces a dash/hyphen/minus sign when the first left sensor of the second set of three sensors is activated and combined with the activation of the third right sensor of the second set of three sensors.

The twelve sensor set in the number mode deletes the previously entered number when the third right sensor of the second set of three sensors is activated twice. The twelve sensor set in the number mode deletes the previously entered numeric data string when the third right sensor of the second set of three sensors is activated three times.

The twelve sensor set in the number mode enters data when the third right sensor of the second set of three sensors is activated and combined with the activation of the second middle sensor of the second set of three sensors.

The twelve sensor set produces a stored data string when at least one sensor of the twelve sensor set is activated for a preset length of time. The twelve sensor set produces a stored data string when at least one sensor of the twelve sensor set is activated and followed by the secondary activation of at least one sensor of the ten numbered sensor set for a preset length of time. The twelve sensor set produces a stored data string when at least one sensor of the twelve sensor set is activated and combined with the activation of at least one sensor of the twelve sensor set for a preset length of time.

The twelve sensor set exits the number mode and enters a cursor mode on the first set of nine sensors, when the third right sensor of the second set of three sensors is activated;

followed by the activation of:

a top row middle sensor or a “2” sensor moves up in a data field;

a right row middle sensor or a “6” sensor moves right in a data field;

a bottom row middle sensor or a “8” sensor moves down in a data field;

a left row middle sensor or a “4” sensor moves left in a data field;

a top row left sensor or a “1” sensor to return home in a data field;

a bottom row left sensor or a “7” sensor moves back in a data field;

a top row right sensor or a “3” sensor moves forward in a data field;

a bottom row right sensor or a “8” sensor moves to the end of a data field; or

a middle row middle sensor or a “5” sensor enters a data field.

The twelve sensor set exits the cursor mode on the first set of nine sensors and re-enters the standard ten sensor number mode when the third right sensor of the second set of three sensors is activated. The twelve sensor set exits the cursor mode on the first set of nine sensors and enters a data character mode when the first left sensor of the second set of three sensors is activated.

The twelve sensor set exits the ten sensor number mode and enters a second ten sensor number mode when the third right sensor of the second set of three sensors is activated.

The twelve sensor set exits the standard ten sensor number mode and enters a second ten sensor number mode when the third right sensor of the second set of three sensors is activated. Activation of a first numbered sensor combined with the activation of a second numbered sensor enters a location mode. Activation of the third numbered sensor produces one of ten location mode exchanges in a secondary area code system.

The twelve sensor set exits the ten sensor number mode and enters a lower-case data character mode on the first set of nine sensors when the first left sensor of the second set of three sensors is activated at least once.

The twelve sensor set exits the ten sensor number mode and enters an upper-case data character mode on the first set of nine sensors when the first left sensor of the second set of three sensors is activated at least once.

The twelve sensor set in the data character mode produces one of three data characters when one sensor of the first set of nine sensors is activated. The twelve sensor set in the data character mode produces one of three data characters when one sensor of the first set of nine sensors is activated and combined with the activation of one sensor of a second set of three sensors.

The twelve sensor set exits the ten sensor number mode and enters a data character mode when a the first left sensor of the second set of three sensors is activated twice.

The twelve sensor set exits the ten sensor number mode and enters a shiftable data character mode on the first set of nine sensors when the first left sensor of the second set of three sensors is activated twice.

The twelve sensor set in the data character mode produces the second middle data character when one sensor of the first set of nine sensors is activated and produces a data character when one sensor of the first set of nine sensors is activated and combined with the activation of one sensor of a second set of three sensors.

The twelve sensor set in the data character mode produces the most frequently used data character when one sensor of the first set of nine sensors is activated and produces a data character when one sensor of the first set of nine sensors is activated and combined with the activation of one sensor of a second set of three sensors.

The twelve sensor set exits the ten sensor number mode and enters a data character mode when a the first left sensor of the second set of three sensors is activated three times.

The twelve sensor set exits the ten sensor number mode and enters a shiftable data character mode on the first set of nine sensors when the first left sensor of the second set of three sensors is activated three times.

The twelve sensor set in the data character mode produces a data character when one sensor of the first set of nine sensors is activated and combined with the activation of one sensor of a second set of three sensors.

The twelve sensor set in the data character mode produces a data character when one sensor of the first set of nine sensors is activated twice and then combined with the activation of one sensor of a second set of three sensors.

The twelve sensor set in the data character mode produces a data character when one sensor of the first set of nine sensors is activated and combined with the activation of one sensor of the first set of nine sensors and then combined with the activation of one sensor of a second set of three sensors.

The twelve sensor set in the data character mode produces a space when one sensor of the first set of nine sensors is activated or when the second middle sensor of the second set of three sensors is activated twice. The twelve sensor set in the data character mode produces a tab function when the second middle sensor of the second set of three sensors is activated three times.

The twelve sensor set in the data character mode produces a dot/period/decimal point when the first left sensor of the second set of three sensors is activated and combined with the activation of the second middle sensor of the second set of three sensors. The twelve sensor set in the data character mode produces a dash/hyphen/minus sign when one sensor of the first set of nine sensors is activated and combined with the activation of the second middle sensor of the second set of three sensors.

The twelve sensor set in the data character mode deletes the previously entered data character when the first left sensor of the second set of three sensors is activated twice. The twelve sensor set in the data character mode deletes the previously entered data character string when the first left sensor of the second set of three sensors is activated three times.

The twelve sensor set in the data character mode enters a punctuation mode when the first left sensor of the second set of three sensors is activated and combined with the activation of the third right sensor of the second set of three sensors. The twelve sensor set in the data character mode enters a second punctuation mode when the first left sensor of the second set of three sensors is activated and combined with the activation of the third right sensor of the second set of three sensors twice. The twelve sensor set in the data character mode enters a third punctuation mode when the first left sensor of the second set of three sensors is activated and combined with the activation of the third right sensor of the second set of three sensors three times.

The twelve sensor set in the data character mode enters data when the third right sensor of the second set of three sensors is activated twice.

The first set of nine sensors exits the data character mode and re-enters the ten sensor number mode when the third right sensor of the second set of three sensors is activated and combined with the activation of the second middle sensor of the second set of three sensors.

The twelve sensor set in the number mode exits the number mode and enters a voice recognition mode when the first left sensor of the second set of three sensors is activated. The twelve sensor set in the number mode exits the number mode and enters a predictive text mode when the first left sensor of the second set of three sensors is activated. The twelve sensor set in the number mode exits the number mode and enters a language mode when the first left sensor of the second set of three sensors is activated.

The twelve sensor set produces audio data through a speaker when at least one sensor of the twelve sensor set is activated. The twelve sensor set produces visual data through a visual display when at least one sensor of the twelve sensors is activated. The twelve sensor set produces tactile data through a tactile display when at least one sensor of the twelve sensors is activated.

The twelve sensor set produces a twelve bit binary code when at least one sensor of the twelve sensors is activated.

The twelve sensor set produces a nine bit binary code combined with a three bit binary code when at least one sensor of the first set of nine sensors is activated or when at least one sensor of the second set of three sensors is activated.

The twelve sensor set produces a nine bit binary code combined with a three bit binary code when at least one sensor of the first set of nine sensors is activated and combined with the activation of at least one sensor of the second set of three sensors.

This method of data representation or data entry, using twelve sensors, produces numbers, all lower-case data, all upper-case data, a space, all punctuation, symbols and control found on a standard keyboard.

### BRIEF DESCRIPTION OF THE DRAWINGS

Further objects, features, and advantages of the present invention will become apparent upon the consideration of the following detailed description of the presently-preferred embodiment when taken in conjunction with the accompanying drawings, wherein:

FIG. 1 shows the standard twelve sensor telephone keypad configuration.

FIG. 2 shows the standard twelve sensor push-button telephone keypad configuration with the “Q” and “Z” located on the number “1” sensor, with a space positioned between the “Q” and “Z”.

FIG. 3 shows a preferred labeling embodiment for the twelve sensor set with the “Q Z” on the one “1” sensor and a punctuation mark included on each numbered sensor.

FIG. 4 shows a preferred labeling embodiment for the twelve sensor set with the “Q-Z” on the one “1” sensor and a punctuation mark included on each numbered sensor.

FIG. 5 shows a preferred labeling embodiment for the twelve sensor set with the “Q Z” on the one “1” sensor and three punctuation marks included on each numbered sensor.

FIG. 6 shows a preferred labeling embodiment for the twelve sensor set with the “Q-Z” on the one “1” sensor and three punctuation marks included on each numbered sensor.

FIG. 7 shows a preferred labeling embodiment for the twelve sensor set with the “Q-Z” on the one “1” sensor and a punctuation mark included on each numbered sensor in a first punctuation mode.

FIG. 8 shows a preferred labeling embodiment for the twelve sensor set with the “Q-Z” on the one “1” sensor and a punctuation mark included on each numbered sensor in a second punctuation mode.

FIG. 9 shows a preferred labeling embodiment for the twelve sensor set with the “Q-Z” on the one 1” sensor and a punctuation mark included on each numbered sensor in a third punctuation mode.

FIG. 10 shows a preferred labeling embodiment for the twelve sensor set with the “Q Z” on the nine “9” sensor and three punctuation marks included on each numbered sensor.

FIG. 11 shows a preferred labeling embodiment for the twelve sensor set with the “Q-Z” on the nine “9” sensor and three punctuation marks included on each numbered sensor.

FIG. 12 shows a one sensor alphabetic coding scheme for use on the preferred twelve sensor set labeling embodiment of FIG. 1 or preferably on the embodiment of FIG. 2, with the “Q Z” on the one “1” sensor.

FIGS. 13A and 13B shows a two sensor alphabetic coding scheme for use on the preferred twelve sensor set labeling embodiment of FIG. 1 or preferably on the embodiment of FIG. 2, with the “Q Z” on the one “1” sensor.

FIGS. 14A and 14B shows a punctuation and two sensor alphabetic coding scheme, with the middle data character requiring one key activation, for use on the preferred twelve sensor set labeling embodiment of FIG. 1 or preferably on the embodiment of FIG. 3, with the “Q Z” on the one “1” sensor.

FIGS. 15A and 15B shows a punctuation and two sensor alphabetic coding scheme, with the most frequently used data character requiring one key activation, for use on the preferred twelve sensor set labeling embodiment of FIG. 1 or preferably on the embodiment of FIG. 3, with the “Q Z” on the one “1” sensor.

FIGS. 16A through 16C shows a punctuation and suitable alphabetic coding scheme, with the middle data character requiring one key activation, for use on the preferred twelve sensor set labeling embodiment of FIG. 1 or preferably on the embodiment of FIG. 3, with the “Q Z” on the one “1” sensor.

FIGS. 17A through 17C shows a punctuation and suitable alphabetic coding scheme, with the most frequently used data character requiring one key activation, for use on the preferred twelve sensor set labeling embodiment of FIG. 1 or preferably on the embodiment of FIG. 3, with the “Q Z” on the one “1” sensor.

FIG. 18 shows a one sensor alphabetic coding scheme for use on the preferred twelve sensor set labeling embodiment of FIG. 11 or preferably on the embodiment of FIG. 10, with the “Q Z” on the nine “9” sensor.

FIGS. 19A and 19B shows a punctuation and two sensor alphabetic coding scheme for use on the preferred twelve sensor set labeling embodiment of FIG. 11 or preferably on the embodiment of FIG. 10, with the “Q Z” on the nine “9” sensor.

FIGS. 20A through 20F shows three punctuation modes and a suitable alphabetic coding scheme for use on the preferred twelve sensor set labeling embodiment of FIG. 1 or preferably on the embodiment of FIG. 5, with the “Q Z” on the one “1” sensor.

### DETAILED DESCRIPTION OF THE PREFERRED EMBODIMENT

In the telephone industry, it is well known that the depression of any given sensor on a standard twelve sensor telephone keypad generates one of twelve pairs of audio tones, dual tone multifrequency signal (DTMF), on the “touch tone” phone, or its digital data counterpart on a digital phone. This invention takes advantage of the customary arrangement of the markings on the face of the standard twelve sensor telephone keypad.

This invention is a method of producing data using a twelve sensor set; a first set of nine sensors, numbered one “1” through nine “9”, with each sensor including three data characters, and a second set of three sensors comprising a first left sensor, a second middle sensor numbered zero “0” and a third right sensor.

Activation of one of the ten numbered sensors, while in the standard number mode, produces the numerical value of the sensor activated. Activation of a first left sensor of a second set of three sensors enters a data character mode. Activating a sensor of a first set of nine sensors, in a data character mode, produces a data character or is combined with the activation of a sensor of a second set of three sensors also produces a data character. The first set of nine sensors exits the data character mode and re-enters the ten sensor number mode when the third right sensor of the second set of three sensors is activated.

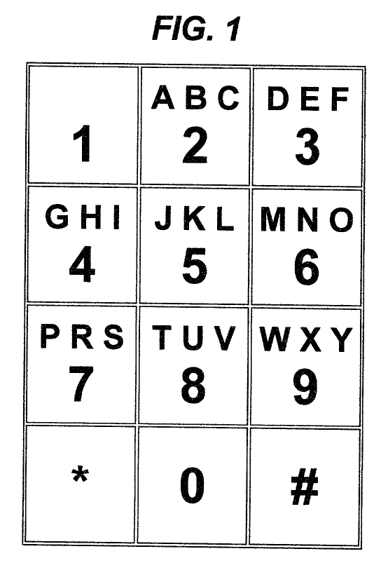

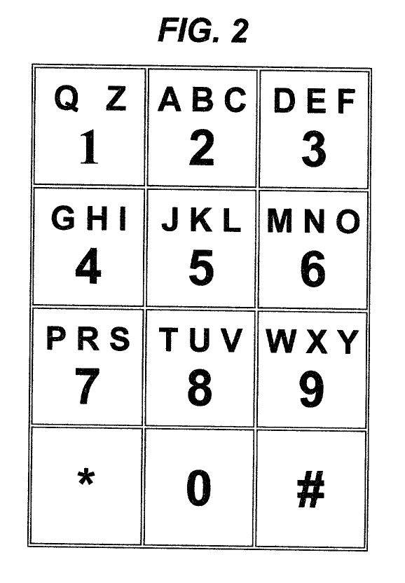

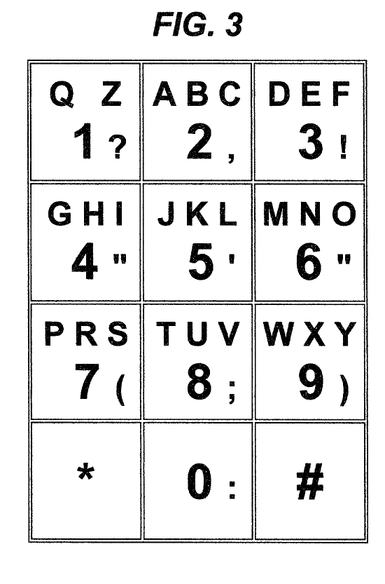

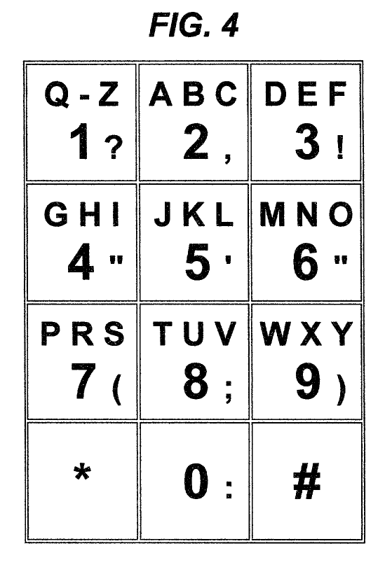

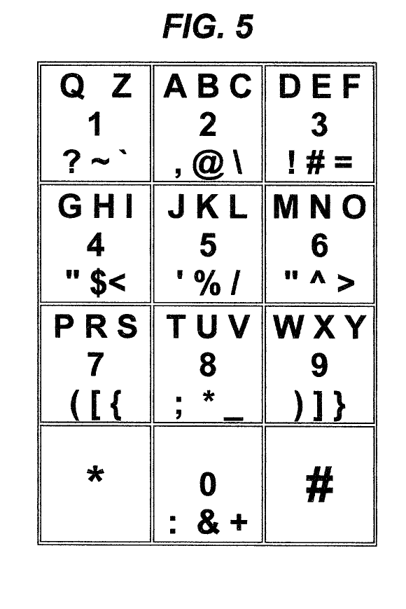

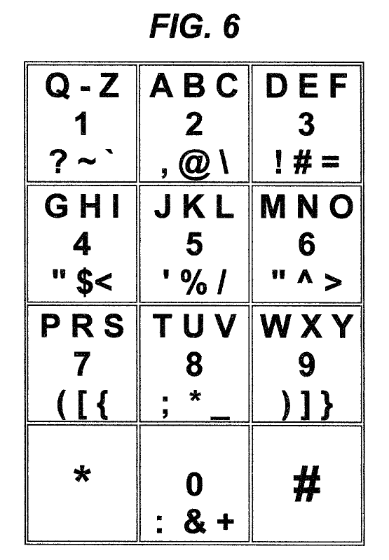

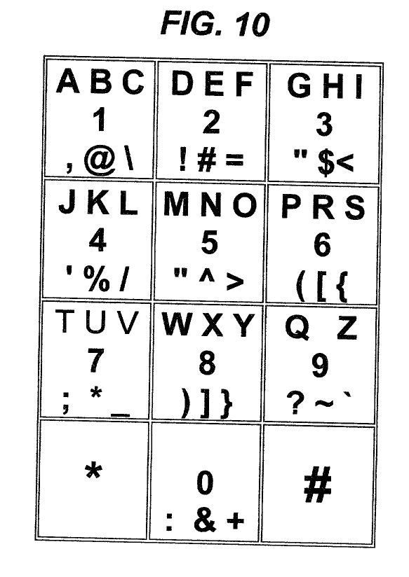

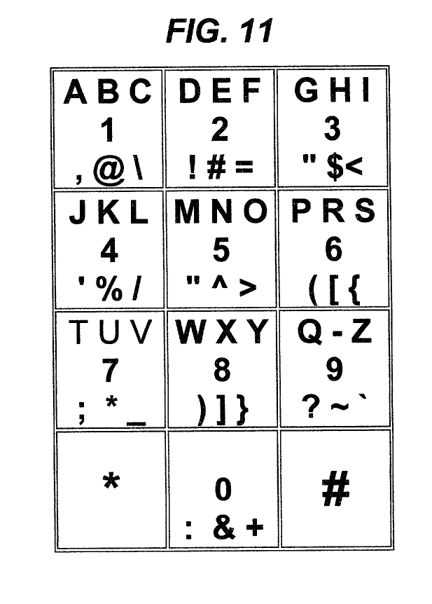

The preferred labeling embodiment of the present invention, shown in FIGS. 1 through 11, uses a twelve sensor set in a data character mode to produce one of three data characters on a first set of nine sensors when one of the sensors is activated, preferably:

the “Q”, “space” or “Z” is produced by the preferred “1” or “9” numbered sensor.

the “Q”, “-” or “Z” is produced by the preferred “1” or “9” numbered sensor,

the “A”, “B” or “C” is produced by the preferred “2” or “1” numbered sensor,

the “D”, “E” or “F” is produced by the preferred “3” or “2” numbered sensor,

the “G”, “H” or “I” is produced by the preferred “4” or “3” numbered sensor,

the “J”, “K” or “L” is produced by the preferred “5” or “4” numbered sensor,

the “M”, “N” or “O” is produced by the preferred “6” or “5” numbered sensor,

the “P”, “R” or “S” is produced by the preferred “7” or “6” numbered sensor,

the “T”, “U” or “V” is produced by the preferred “8” or “7” numbered sensor, and

the “W”, “X” or “Y” is produced by the preferred “9” or “8” numbered sensor.

The preferred embodiment of the present invention includes:

A method of producing data using a twelve sensor set, with a first set of nine sensors, numbered one “1” through nine “9”, with each sensor including three data characters, and a second set of three sensors comprising a first left preferred asterisk “*” sensor, a second middle sensor numbered zero “0” and a third right preferred pound “#” sensor. The twelve sensor set produces numeric data in the standard number mode, when one of the ten numbered sensors is activated. The twelve sensor set exits the ten sensor number mode and enters a data character mode on the first set of nine sensors when the first left preferred asterisk “*” sensor of the second set of three sensors is activated. The twelve sensor set can also exit the ten sensor number mode and enter a data character mode when the first left preferred asterisk “*” sensor of the second set of three sensors is activated two or three times. The twelve sensor set in the data character mode produces one of three data characters when one sensor of the first set of nine sensors is activated or when one sensor of the first set of nine sensors is activated and combined with the activation of one sensor of a second set of three sensors. The first set of nine sensors exits the data character mode and re-enters the ten sensor number mode when the third right preferred pound “#” sensor of the second set of three sensors is activated. The first set of nine sensors can also exit the data character mode and re-enter the ten sensor number mode when the third right preferred pound “#” sensor of the second set of three sensors is activated and combined with the activation of the second middle sensor of the second set of three sensors.

The twelve sensor set in the number mode produces a dot/period/decimal point when the first left preferred asterisk “*” sensor of the second set of three sensors is activated and combined with the activation of the second middle sensor of the second set of three sensors. The twelve sensor set in the number mode produces a dash/hyphen/minus sign when the first left preferred asterisk “*” sensor of the second set of three sensors is activated and combined with the activation of the third right preferred pound “#” sensor of the second set of three sensors.

The twelve sensor set in the number mode deletes the previously entered number when the third right preferred pound “#” sensor of the second set of three sensors is activated twice. The twelve sensor set in the number mode deletes the previously entered numeric data string when the third right preferred pound “#” sensor of the second set of three sensors is activated three times.

The twelve sensor set in the number mode enters data when the third right preferred pound “#” sensor of the second set of three sensors is activated and combined with the activation of the second middle sensor of the second set of three sensors.

The twelve sensor set produces a stored data string when at least one sensor of the twelve sensor set is activated for a preset length of time. The twelve sensor set produces a stored data string when at least one sensor of the twelve sensor set is activated and followed by the secondary activation of at least one sensor of the ten numbered sensor set for a preset length of time. The twelve sensor set produces a stored data string when at least one sensor of the twelve sensor set is activated and combined with the activation of at least one sensor of the twelve sensor set for a preset length of time.

The twelve sensor set exits the number mode and enters a cursor mode on the first set of nine sensors, when the third right preferred pound “W” sensor of the second set of three sensors is activated; followed by the activation of:

a top row middle sensor or a “2” sensor moves up in a data field;

a right row middle sensor or a “6” sensor moves right in a data field;

a bottom row middle sensor or a “8” sensor moves down in a data field;

a left row middle sensor or a “4” sensor moves left in a data field;

a top row left sensor or a “1” sensor to return home in a data field;

a bottom row left sensor or a “7” sensor moves back in a data field;

a top row right sensor or a “3” sensor moves forward in a data field;

a bottom row right sensor or a “8” sensor moves to the end of a data field; or

a middle row middle sensor or a “5” sensor enters a data field.

The twelve sensor set exits the cursor mode on the first set of nine sensors and re-enters the standard ten sensor number mode when the third right preferred pound “#” sensor of the second set of three sensors is activated. The twelve sensor set exits the cursor mode on the first set of nine sensors and enters a data character mode when the first left preferred asterisk “*” sensor of the second set of three sensors is activated.

The twelve sensor set exits the ten sensor number mode and enters a second ten sensor number mode when the third right sensor of the second set of three sensors is activated.

The twelve sensor set exits the standard ten sensor number mode and enters a second ten sensor number mode when the third right preferred pound “#” sensor of the second set of three sensors is activated. Activation of a first numbered sensor combined with the activation of a second numbered sensor enters a location mode. Activation of the third numbered sensor produces one of ten location mode exchanges in a secondary area code system.

The twelve sensor set exits the ten sensor number mode and enters a lower-case data character mode on the first set of nine sensors when the first left preferred asterisk “*” sensor of the second set of three sensors is activated at least once.

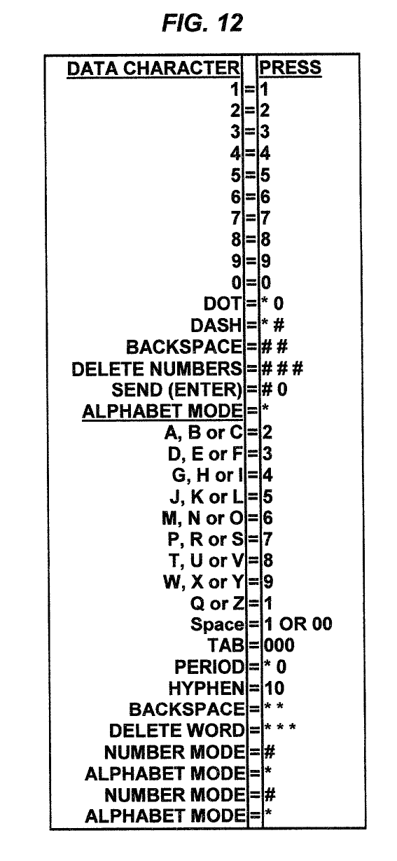

The twelve sensor set exits the ten sensor number mode and enters an upper-case data character mode on the first set of nine sensors, shown in FIG. 12, when the first left preferred asterisk “*” sensor of the second set of three sensors is activated at least once.

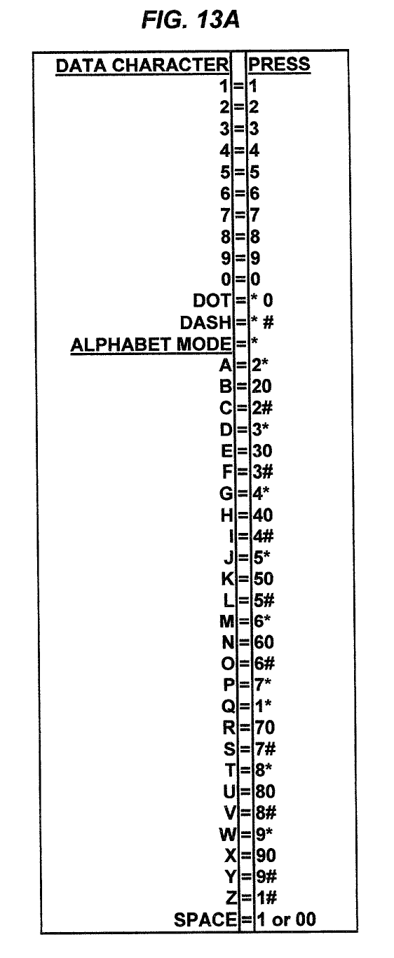

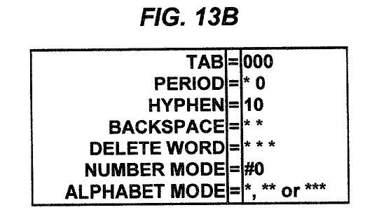

The twelve sensor set in the data character mode produces one of three data characters, shown in FIG. 13, when one sensor of the first set of nine sensors is; activated and combined with the activation of:

the first left preferred asterisk “*” sensor for producing a first left data character;

the second middle sensor for producing a second middle data character; or

the third right preferred pound “#” sensor for producing a third right data character.

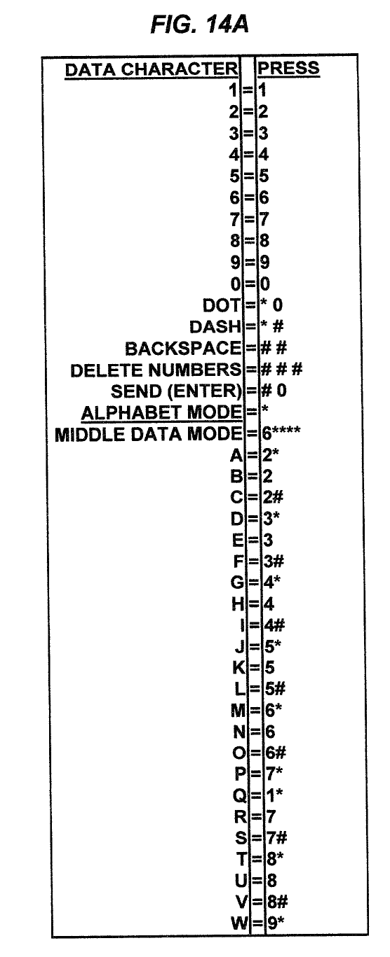

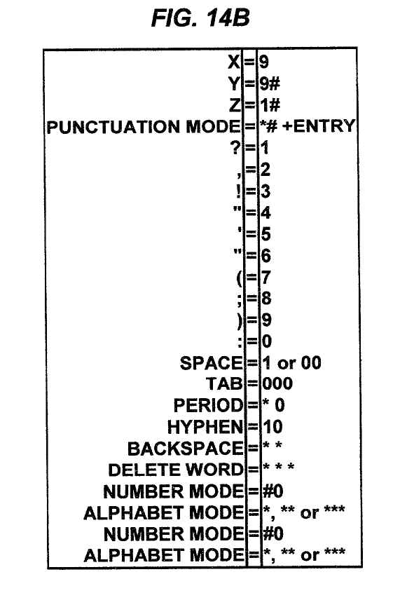

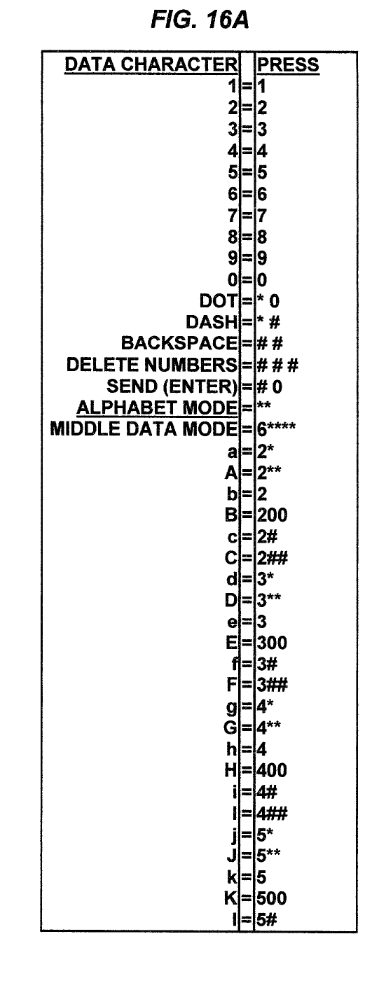

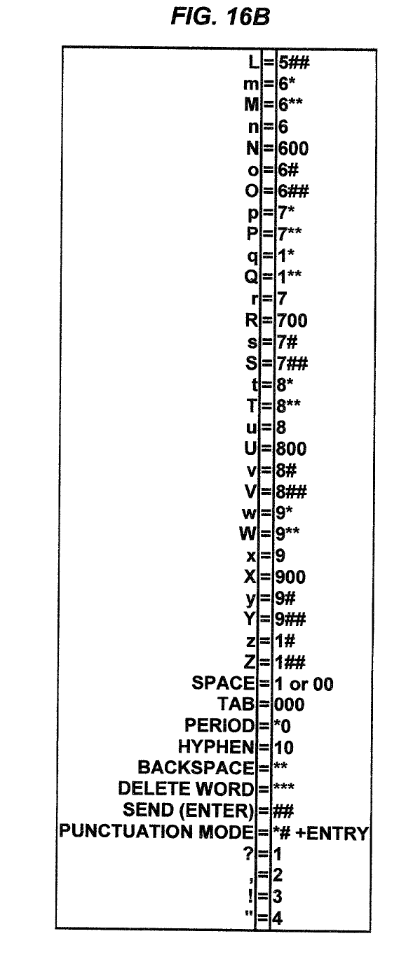

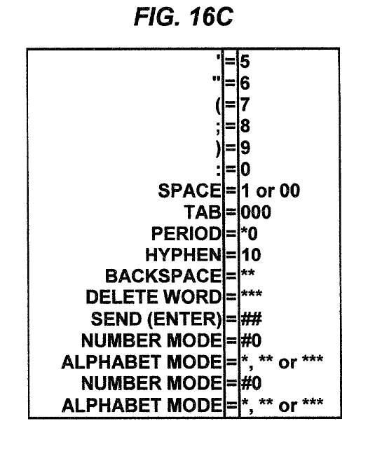

The twelve sensor set in the data character mode produces a second middle data character, shown in FIGS. 14 and 16, when one sensor of the first set of nine sensors is activated or is combined with the activation of:

the first left preferred asterisk “*” sensor for producing a first left data character; or

the third right preferred pound “#” sensor for producing a third right data character.

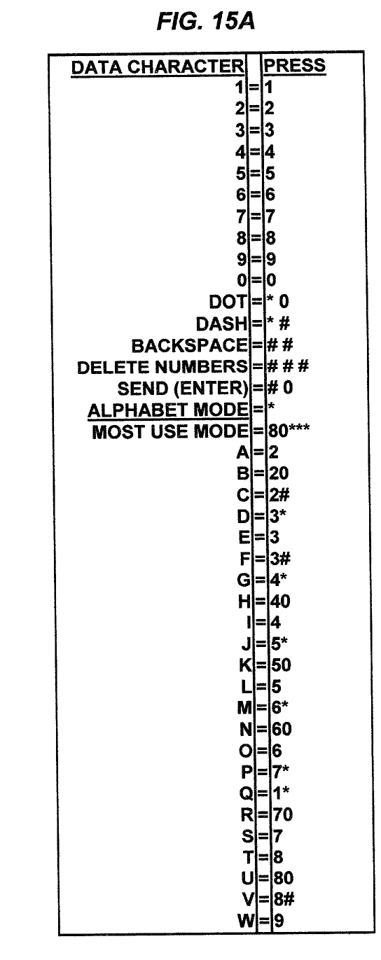

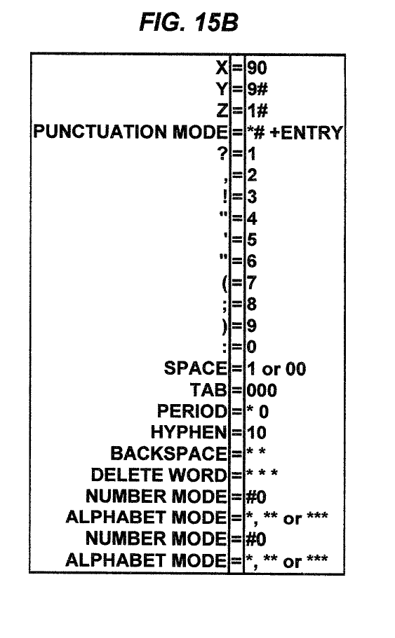

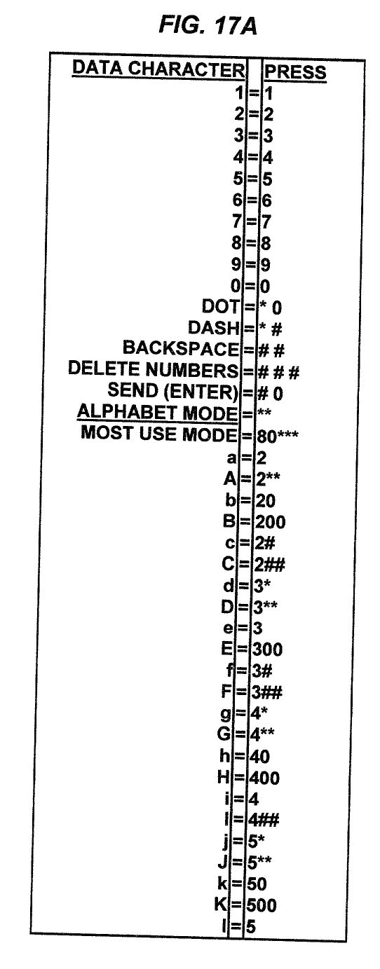

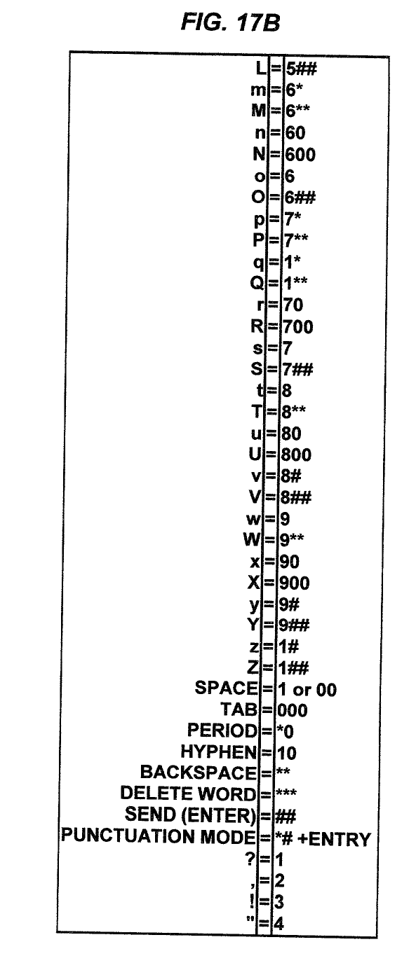

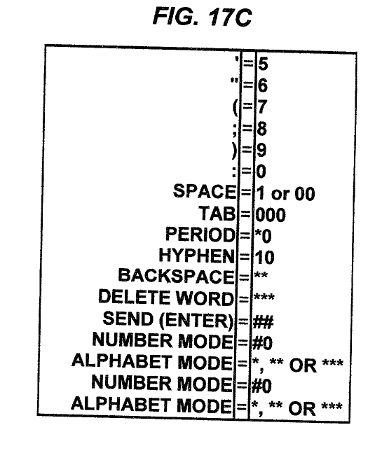

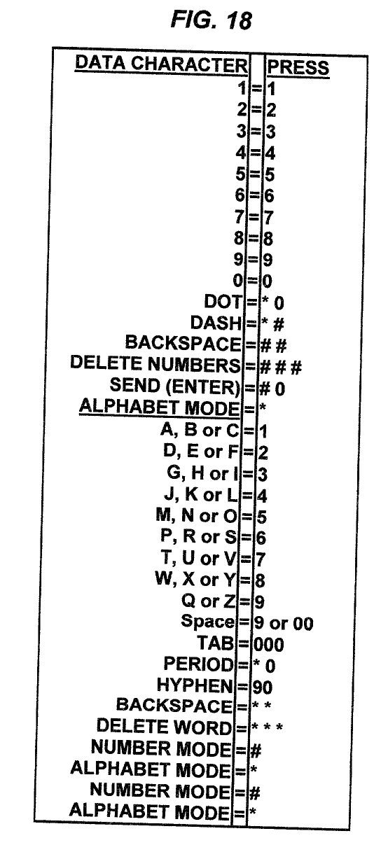

The twelve sensor set in the data character mode produces the most frequently used data character, shown in FIGS. 15 and 17, when one sensor of the first set of nine sensors is activated or is combined with the activation of:

the first left preferred asterisk “*” sensor for producing a first left data character;

the second middle sensor for producing a second middle data character; or the third right preferred pound “#” sensor for producing a third right data character.

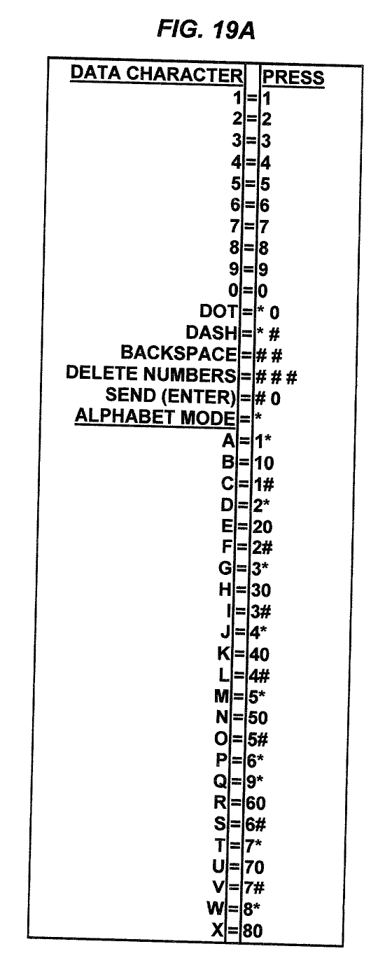

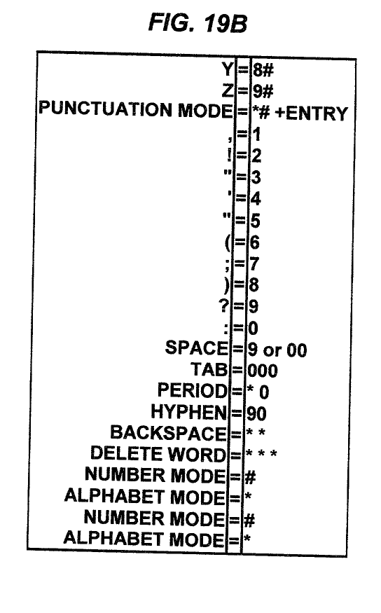

The present invention provides a method for entering alphabetic data characters, shown in FIGS. 13 and 19, including a space or the dash/hyphen/minus sign, produced by one of nine sensors numbered one “1” through nine “9”, or combined with the activation of one of three sensors; preferably the first left preferred asterisk “*” sensor, the second middle preferred zero “0” sensor, or the third right preferred pound sign “#” sensor.

Activation of a sensor of a first set of nine sensors, with the desired alphabetic data, combined with the activation of the first left preferred asterisk “*” sensor produces the first left position data character, the second middle preferred zero “0” sensor produces the second middle position data character, or the third right preferred pound sign “#” sensor produces the third right position data character.

The “A” or “a” is produced by the activation of the preferred “2” or “1” sensor or is combined with the activation of the first left preferred asterisk “*” sensor.

The “B” or “b” is produced by the activation of the preferred “2” or “1” sensor or is combined with the activation of the second middle preferred zero “0” sensor.

The “C” or “c” is produced by the activation of the preferred “2” or “1” sensor or is combined with the activation of the third right preferred pound sign “#” sensor.

The “D” or “d” is produced by the activation of the preferred “3” or “2” sensor or is combined with the activation of the first left preferred asterisk “*” sensor.

The “E” or “e” is produced by the activation of the preferred “3” or “2” sensor or is combined with the activation of the second middle preferred zero “0” sensor.

The “F” or “f” is produced by the activation of the preferred “3” or “2” sensor or is combined with the activation of the third right preferred pound sign “#” sensor.

The “G” or “g” is produced by the activation of the preferred “4” or “3” sensor or is combined with the activation of the first left preferred asterisk “*” sensor.

The “H” or “h” is produced by the activation of the preferred “4” or “3” sensor or is combined with the activation of the second middle preferred zero “0” sensor.

The “I” or “i” is produced by the activation of the preferred “4” or “3” sensor or is combined with the activation of the third right preferred pound sign “#” sensor.

The “J” or “j” is produced by the activation of the preferred “5” or “4” sensor or is combined with the activation of the first left preferred asterisk “*” sensor.

The “K” or “k” is produced by the activation of the preferred “5” or “4” sensor or is combined with the activation of the second middle preferred zero “0” sensor.

The “L” or “I” is produced by the activation of the preferred “5” or “4” sensor or is combined with the activation of the third right preferred pound sign “#” sensor.

The “M” or “m” is produced by the activation of the preferred “6” or “5” sensor or is combined with the activation of the first left preferred asterisk “*” sensor.

The “N” or “n” is produced by the activation of the preferred “6” or “5” sensor or is combined with the activation of the second middle preferred zero “0” sensor.

The “O” or “o” is produced by the activation of the preferred “6” or “5” sensor or is combined with the activation of the third right preferred pound sign “#” sensor.

The “P” or “p” is produced by the activation of the preferred “7” or “6” sensor or is combined with the activation of the first left preferred asterisk “*” sensor.

The “Q” or “q” is produced by the activation of the preferred “1” or “9” sensor or is combined with the activation of the first left preferred asterisk “*” sensor.

The “R” or ““r” is produced by the activation of the preferred “7” or “6” sensor or is combined with the activation of the second middle preferred zero “0” sensor.

The “S” or “s” is produced by the activation of the preferred “7” or “6” sensor or is combined with the activation of the third right preferred pound sign “*” sensor.

The “T” or “t” is produced by the activation of the preferred “8” or “7” sensor or is combined with the activation of the first left preferred asterisk “*” sensor.

The “U” or “u” is produced by the activation of the preferred “8” or “7” sensor or is combined with the activation of the second middle preferred zero “0” sensor.

The “V” or “v” is produced by the activation of the preferred “8” or “7” sensor or is combined with the activation of the third right preferred pound sign “#” sensor.

The “W” or “w” is produced by the activation of the preferred “9” or “8” sensor or is combined with the activation of the first left preferred asterisk “*” sensor.

The “X” or “x” is produced by the activation of the preferred “9” or “8” sensor or is combined with the activation of the second middle preferred zero “0” sensor.

The “Y” or “y” is produced by the activation of the preferred “9” or “8” sensor or is combined with the activation of the third right preferred pound sign “#” sensor.

The “Z” or “z” is produced by the activation of the preferred “1” or “9” sensor or is combined with the activation of the third right preferred pound sign “#” sensor.

The “space” is produced by the activation of the preferred “1” or “9” sensor or by the activation of the second middle zero “0” sensor twice.

The dash/hyphen/minus sign is produced by the activation of the preferred “1” or “9” sensor or is combined with the activation of the second middle zero “0” sensor.

The twelve sensor set exits the ten sensor number mode and enters a data character mode when the first left preferred asterisk “*” sensor of the second set of three sensors is activated twice.

The twelve sensor set exits the ten sensor number mode and enters a shiftable data character mode on the first set of nine sensors when the first left preferred asterisk “*” sensor of the second set of three sensors is activated twice.

The twelve sensor set exits the ten sensor number mode and enters a data character mode when the first left preferred asterisk “*” sensor of the second set of three sensors is activated three times.

The twelve sensor set exits the ten sensor number mode and enters a shiftable data character mode on the first set of nine sensors when the first left preferred asterisk “*” sensor of the second set of three sensors is activated three times.

The present invention provides a method for entering lower-case and upper-case alphabetic data, shown in FIGS. 16, 17 and 20. When the first left preferred asterisk “*” sensor is depressed twice or three times while in the number mode, the apparatus enters into a two sensor lower-case and three sensor upper-case alphabet mode. Depressing the sensor of a first set of nine sensors, with the desired alphabetic data, combined with the activation of the first left preferred asterisk “*” sensor produces the first left position data character, and secondary activation of the sensor of the second set of three sensors produces the upper-case character the second middle preferred zero “0 ” sensor produces the second middle position data character, and secondary activation of the sensor of the second set of three sensors produces the upper-case character, or the third right preferred pound sign “#” sensor produces the third right position data character, and secondary activation of the sensor of the second set of three sensors produces the upper-case character.

The twelve sensor set in the data character mode produces a data character, shown in FIGS. 16, 17 and 20, when one sensor of the first set of nine sensors is activated and is combined with the activation of:

the first left preferred asterisk “*” sensor for producing a first left lower-case data character;

the second middle sensor for producing a second middle lower-case data character;

the third right preferred pound “#” sensor for producing a third right lower-case data character;

the first left preferred asterisk “*” sensor twice for producing a first left upper-case data character;

the second middle sensor twice for producing a second middle upper-case data character; or

the third right preferred pound “#” sensor twice for producing a third right upper-case data character.

The lower-case “a” is produced by the activation of the preferred “2” or “1” sensor or is combined with the activation of the first left preferred asterisk “*” sensor; and the upper-case “A” is produced by the activation of the preferred “2” or “1” sensor combined with the activation of the first left preferred asterisk “*” sensor twice.

The lower-case “b” is produced by the activation of the preferred “2” or “1” sensor or is combined with the activation of the second middle preferred zero “0” sensor; and the upper-case “B” is produced by the activation of the preferred “2” or 1” sensor combined with the activation of the second middle preferred zero “0” sensor twice.

The lower-case “c” is produced by the activation of the preferred “2” or “1” sensor or is combined with the activation of the third right preferred number “#” sensor; and the upper-case “C” is produced by the activation of the preferred “2” or “1” sensor combined with the activation of the third right preferred number “#” sensor twice.

The lower-case “d” is produced by the activation of the preferred “3” or “2” sensor or is combined with the activation of the first left preferred asterisk “*” sensor; and the upper-case “D” is produced by the activation of the preferred “3” or “2” sensor combined with the activation of the first left preferred asterisk “*” sensor twice.

The lower-case “e” is produced by the activation of the preferred “3” or “2” sensor or is combined with the activation of the second middle preferred zero “0” sensor; and the upper-case “E” is produced by the activation of the preferred “3” or “2” sensor combined with the activation of the second middle preferred zero “0” sensor twice.

The lower-case “f” is produced by the activation of the preferred “3” or “2” sensor or is combined with the activation of the third right preferred number “#” sensor; and the upper-case “F” is produced by the activation of the preferred “3” or “2” sensor combined with the activation of the third right preferred number “#” sensor twice.

The lower-case “g” is produced by the activation of the preferred “4” or “3” sensor or is combined with the activation of the first left preferred asterisk “*” sensor; and the upper-case “G” is produced by the activation of the preferred “4” or “3” sensor combined with the activation of the first left preferred asterisk “*” sensor twice.

The lower-case “h” is produced by the activation of the preferred “4” or “3” sensor or is combined with the activation of the second middle preferred zero “0” sensor; and the upper-case “H” is produced by the activation of the preferred “4” or “3” sensor combined with the activation of the second middle preferred zero “0” sensor twice.

The lower-case “i” is produced by the activation of the preferred “4” or “3” sensor or is combined with the activation of the third right preferred number “#” sensor; and the upper-case “I” is produced by the activation of the preferred “4” or “3” sensor combined with the activation of the third right preferred number “#” sensor twice.

The lower-case “j” is produced by the activation of the preferred “5” or “4” sensor or is combined with the activation of the first left preferred asterisk “*” sensor; and the upper-case “J” is produced by the activation of the preferred “5” or “4” sensor combined with the activation of the first left preferred asterisk “*” sensor twice.

The lower-case “k” is produced by the activation of the preferred “5” or “4” sensor or is combined with the activation of the second middle preferred zero “0” sensor; and the upper-case “K” is produced by the activation of the preferred “5” or “4” sensor combined with the activation of the second middle preferred zero “0” sensor twice.

The lower-case “I” is produced by the activation of the preferred “5” or “4” sensor or is combined with the activation of the third right preferred pound sign “#” sensor; and the upper-case “L” is produced by the activation of the preferred “5” or “4” sensor combined with the activation of the third right preferred pound sign “#” sensor twice.

The lower-case “m” is produced by the activation of the preferred “6” or “5” sensor or is combined with the activation of the first left preferred asterisk “*” sensor; and the upper-case “M” is produced by the activation of the preferred “6” or “5” sensor combined with the activation of the first left preferred asterisk “*” sensor twice.

The lower-case “n” is produced by the activation of the preferred “6” or “5” sensor or is combined with the activation of the second middle preferred zero “0” sensor; and the upper-case “N” is produced by the activation of the preferred “6” or “5” sensor combined with the activation of the second middle preferred zero “0” sensor twice.

The lower-case “o” is produced by the activation of the preferred “6” or “5” sensor or is combined with the activation of the third right preferred pound sign “#” sensor; and the upper-case “O” is produced by the activation of the preferred “6” or “5” sensor combined with the activation of the third right preferred pound sign “#” sensor twice.

The lower-case “p” is produced by the activation of the preferred “7” or “6” sensor or is combined with the activation of the first left preferred asterisk “*” sensor; and the upper-case “P” is produced by the activation of the preferred “7” or “6” sensor combined with the activation of the first left preferred asterisk “*” sensor twice.

The lower-case “q” is produced by the activation of the preferred “1” or “9” sensor or is combined with the activation of the first left preferred asterisk “*” sensor; and the upper-case “Q” is produced by the activation of the preferred “1” or “9” sensor combined with the activation of the first left preferred asterisk “*” sensor twice.

The lower-case “r” is produced by the activation of the preferred “7” or “6” sensor or is combined with the activation of the second middle preferred zero “0” sensor; and the upper-case “R” is produced by the activation of the preferred “7” or “6” sensor combined with the activation of the second middle preferred zero “0” sensor twice.

The lower-case “s” is produced by the activation of the preferred “7” or “6” sensor or is combined with the activation of the third right preferred pound sign “#” sensor; and the upper-case “S” is produced by the activation of the preferred “7” or “6” sensor combined with the activation of the third right preferred pound sign “#” sensor twice.

The lower-case “t” is produced by the activation of the preferred “8” or “7” sensor or is combined with the activation of the first left preferred asterisk “*” sensor; and the upper-case “T” is produced by the activation of the preferred “8” or “7” sensor combined with the activation of the first left preferred asterisk “*” sensor twice.

The lower-case “u” is produced by the activation of the preferred “8” or “7” sensor or is combined with the activation of the second middle preferred zero “0” sensor; and the upper-case “U” is produced by the activation of the preferred “8” or “7” sensor combined with the activation of the second middle preferred zero “0” sensor twice.

The lower-case “v” is produced by the activation of the preferred “8” or “7” sensor or is combined with the activation of the third right preferred pound sign “#” sensor; and the upper-case “V” is produced by the activation of the preferred “8” or “7” sensor combined with the activation of the third right preferred pound sign “#” sensor twice.

The lower-case “w” is produced by the activation of the preferred “9” or “8” sensor or is combined with the activation of the first left preferred asterisk “*” sensor; and the upper-case “W” is produced by the activation of the preferred “9” or “8” sensor combined with the activation of the first left preferred asterisk “*” sensor twice.

The lower-case “x” is produced by the activation of the preferred “9” or “8” sensor or is combined with the activation of the second middle preferred zero “0” sensor; and the upper-case “X” is produced by the activation of the preferred “9” or “8” sensor combined with the activation of the second middle preferred zero “0” sensor twice.

The lower-case “y” is produced by the activation of the preferred “9” or “8” sensor or is combined with the activation of the third right preferred pound sign “#” sensor; and the upper-case “Y” is produced by the activation of the preferred “9” or “8” sensor combined with the activation of the third right preferred pound sign “#” sensor twice.

The lower-case “z” is produced by the activation of the preferred “1” or “9” sensor or is combined with the activation of the third right preferred pound sign “#” sensor; and the upper-case “Z” is produced by the activation of the preferred “1” or “9” sensor combined with the activation of the third right preferred pound sign “#” sensor twice.

The “space” is produced by the activation of the preferred “1” or “9” sensor or by the activation of the second middle preferred zero “0” sensor twice.

The dash/hyphen/minus sign is produced by the activation of the preferred “1” or “9” sensor or is combined with the activation of the second middle zero “0” sensor.

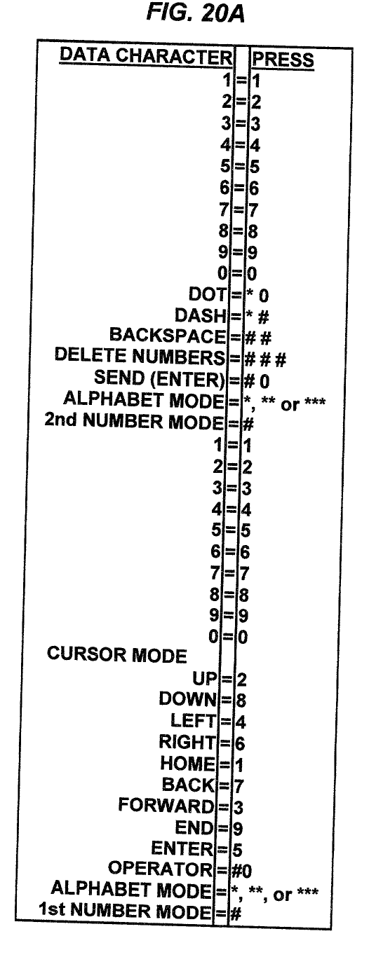

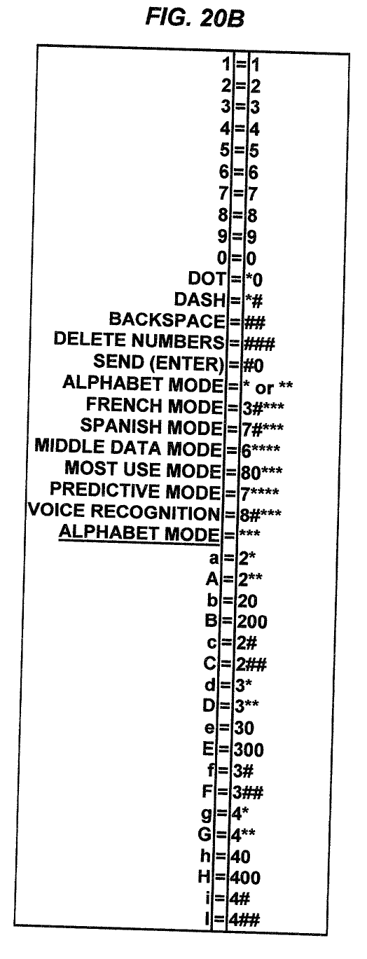

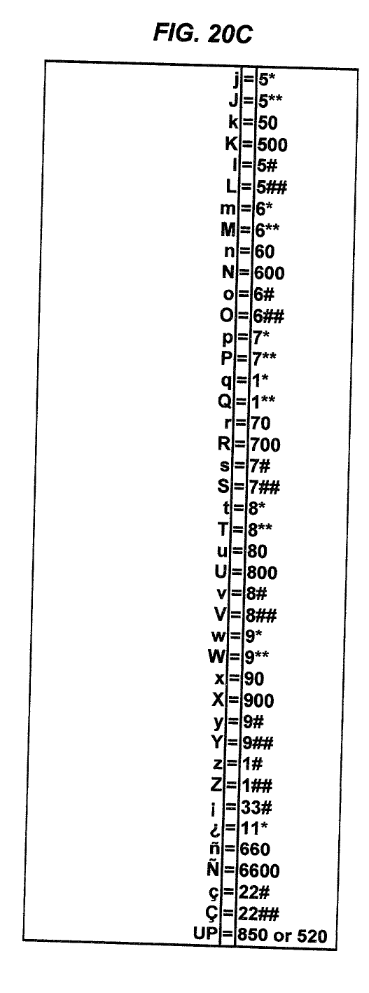

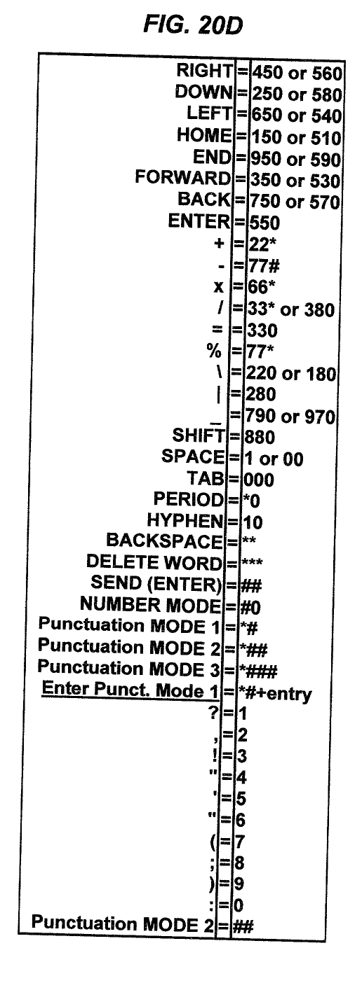

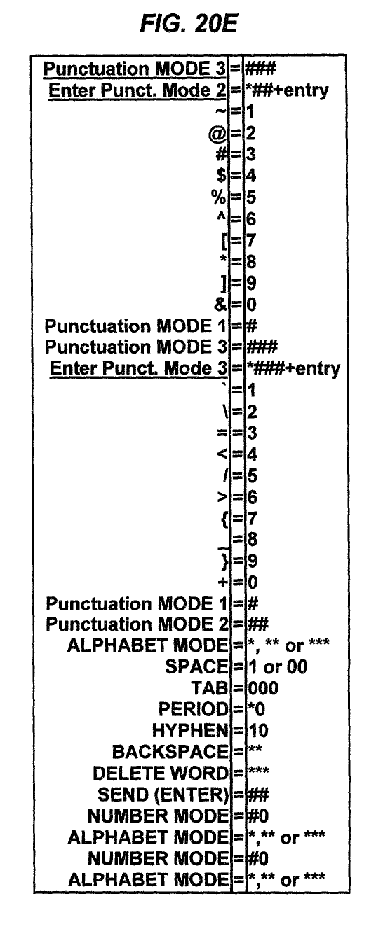

The twelve sensor set in the data character mode produces a data character, shown in FIG. 20, when one sensor of the first set of nine sensors is activated twice and is combined with the activation of:

the first left preferred asterisk “*” sensor for producing the data character;

the second middle sensor for producing the data character;

the third right preferred pound “#” sensor for producing the data character;

the first left preferred asterisk sensor twice for producing an upper-case data character;

the second middle sensor twice for producing an upper-case data character; or

the third right preferred pound “#” sensor twice for producing an upper-case data character.

The twelve sensor set in the data character mode produces a data character, shown in FIG. 20, when one sensor of the first set of nine sensors is activated and combined with the activation of one sensor of the first set of nine sensors and combined with the activation of:

the first left preferred asterisk “*” sensor for producing the data character;

the second middle sensor for producing the data character;

the third right preferred pound “#” sensor for producing the data character;

the first left preferred asterisk “*” sensor twice for producing an upper-case data character;

the second middle sensor twice for producing an upper-case data character; or

the third right preferred pound “#” sensor twice for producing an upper-case data character.

The twelve sensor set in the data character mode produces a space when one sensor of the first set of nine sensors is activated or when the second middle sensor of the second set of three sensors is activated twice. The twelve sensor set in the data character mode produces a tab function when the second middle sensor of the second set of three sensors is activated three times.

The twelve sensor set in the data character mode produces a dot/period/decimal point when the first left preferred asterisk “*” is sensor of the second set of three sensors is activated and combined with the activation of the second middle sensor of the second set of three sensors. The twelve sensor set in the data character mode produces a dash/hyphen/minus sign when one sensor of the first set of nine sensors is activated and combined with the activation of the second middle sensor of the second set of three sensors.

The twelve sensor set in the data character mode deletes the previously entered data character when the first left preferred asterisk “*” sensor of the second set of three sensors is activated twice. The twelve sensor set in the data character mode deletes the previously entered data character string when the first left preferred asterisk “*” sensor of the second set of three sensors is activated three times.

The twelve sensor set in the data character mode enters a punctuation mode, shown in FIGS. 14 through 17 and FIG. 19, when the first left preferred asterisk “*” sensor of the second set of three sensors is activated and combined with the activation of the third right preferred pound “#” sensor of the second set of three sensors. The twelve sensor set in the data character mode enters a first punctuation mode, shown in FIG. 20, when the first left preferred asterisk “*” sensor of the second set of three sensors is activated and combined with the activation of the third right preferred pound “#” sensor of the second set of three sensors. The twelve sensor set in the data character mode enters a second punctuation mode when the first left preferred asterisk “*” sensor of the second set of three sensors is activated and combined with the activation of the third right preferred pound “#” sensor of the second set of three sensors twice, shown in FIG. 20. The twelve sensor set in the data character mode enters a third punctuation mode when the first left preferred asterisk “*” sensor of the second set of three sensors is activated and combined with the activation of the third right preferred pound “#” sensor of the second set of three sensors three times, shown in FIG. 20.

Activation of the first left preferred asterisk “*” sensor, while in an alphabet mode, combined with the activation of the third right preferred pound sign “#” sensor, enters a punctuation mode, which is then followed by the desired punctuation data sensor represented on one of the ten sensors numbered one “1” through zero “0”, where the activation of the preferred “1” or “9” sensor produces a question mark “?”, where the activation of the preferred “2” or “1” sensor produces a comma “,”, where the activation of the preferred “3” or “2” sensor produces an exclamation mark “!”, where the activation of the preferred “4” or “3” sensor produces an open quote ““”, where the activation of the preferred “5” or “4” sensor produces an apostrophe/acute accent “'” where the activation of the preferred “6” or “5” sensor produces a closed quote “””, where the activation of the preferred “7” or “6” sensor produces an open parenthesis “(”, where the activation of the preferred “8” or “7” sensor produces a semi-colon “;”, where the activation of the preferred “9” or “8” sensor produces a closed parenthesis “)”, where the activation of the preferred “0” sensor produces a colon “:”, and after activation of the desired punctuation sensor the twelve sensor set returns to the previous alphabet mode.

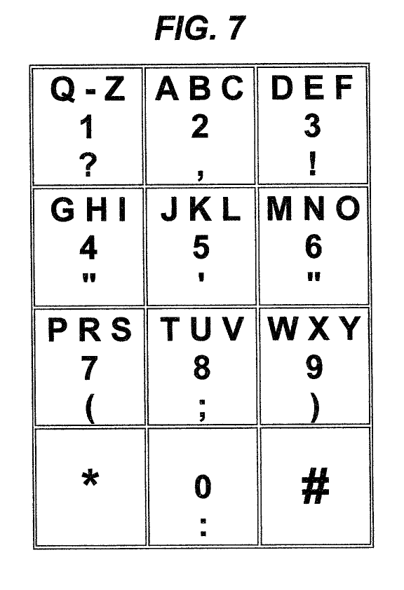

Activation of the first left preferred asterisk “*” sensor three times, shown in FIG. 7 and FIG. 20, enters an alphabet mode, wherein activation of the first left preferred asterisk “*” sensor combined with the activation of the third right preferred pound sign “#” sensor, enters a first punctuation mode, which is then followed by the desired punctuation data sensor represented on one of the ten sensors numbered one “1” through zero “0”, where the activation of the preferred “1” or “9” sensor produces a question mark “?”, where the activation of the preferred “2” or “1” sensor produces a comma “,”, where the activation of the preferred “3” or “2” sensor produces an exclamation mark “!”, where the activation of the preferred “4” or “3” sensor produces an open quote ““” where the activation of the preferred “5” or “4” sensor produces an apostrophe/acute accent “'”, where the activation of the preferred “6” or “5” sensor produces a closed quote “”“, where the activation of the preferred “7” or “6” sensor produces an open parenthesis “(”, where the activation of the preferred “8” or “7” sensor produces a semi-colon “;”, where the activation of the preferred “9” or “8” sensor produces a closed parenthesis “)”, where the activation of the preferred “0” sensor produces a colon “:”. Activation of the third right preferred pound sign “#” sensor twice enters the second punctuation mode. Activation of the third right preferred pound sign “#” sensor three times enters the third punctuation mode. Activation of the first left preferred asterisk “*” sensor re-enters the alphabet mode.

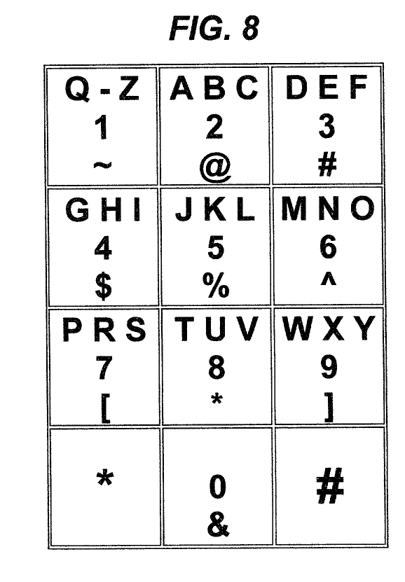

Activation of the first left preferred asterisk “*” sensor three times, shown in FIG. 8 and FIG. 20, enters an alphabet mode, wherein activation of the first left preferred asterisk “*” sensor combined with the activation of the third right preferred pound sign “#” sensor twice, enters a second punctuation mode, which is then followed by the desired punctuation data sensor represented on one of the ten sensors numbered one “1” through zero “0”, where the activation of the preferred “1” or “9” sensor produces a tilde “18 ”, where the activation of the preferred “2” or “1” sensor produces an at symbol “@”, where the activation of the preferred “3” or “2” sensor produces a pound sign where the activation of the preferred “4” or “3” sensor produces a dollar sign “$”, where the activation of the preferred “5” or “4” sensor produces a percent sign “%”, where the activation of the preferred “6” or “5” sensor produces a circumflex accent “ˆ ”, where the activation of the preferred “7” or 6” sensor produces a left bracket “[”, where the activation of the preferred “8” or “7” sensor produces an asterisk “*”, where the activation of the preferred “9” or “8” sensor produces a right “]”, where the activation of the preferred “0” sensor produces a ampersand “&”. Activation of the third right preferred pound sign “#” sensor enters the first punctuation mode. Activation of the third right preferred pound sign “#” sensor three times enters the third punctuation mode. Activation of the first left preferred asterisk “*” sensor re-enters the alphabet mode.

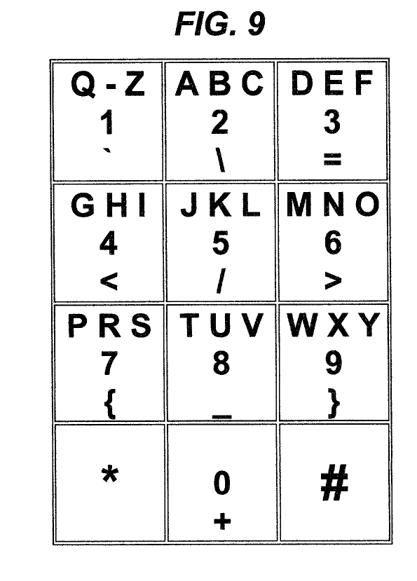

Activation of the first left preferred asterisk “*” sensor three times, shown in FIG. 9 and FIG. 20, enters an alphabet mode, wherein activation of the first left preferred asterisk “*” sensor combined with the activation of the third right preferred pound sign “#” sensor three times, enters a third punctuation mode, which is then followed by the desired punctuation data sensor represented on one of the ten sensors numbered one “1” through zero “0”, where the activation of the preferred “1” or “0” sensor produces a grave accent “`”, where the activation of the preferred “2” or “1” sensor produces a backslash “\”, where the activation of the preferred “3” or “2” sensor produces an equal sign “=”, where the activation of the preferred “4” or “3” sensor produces a less than sign “<”, where the activation of the preferred “5” or “4” sensor produces a slash “/”, where the activation of the preferred “6” or “5” sensor produces a greater than sign “>”, where the activation of the preferred “7” or “6” sensor produces a left parenthesis “{”, where the activation of the preferred “8” or “7” sensor produces an underscore “_”, where the activation of the preferred “9” or “8” sensor produces a right parenthesis “}”, where the activation of the preferred “0” sensor produces a plus sign “+”. Activation of the third right preferred pound sign “#” sensor enters the first punctuation mode. Activation of the third right preferred pound sign “#” sensor twice enters the second punctuation mode. Activation of the first left preferred asterisk “*” sensor re-enters the alphabet mode.

The twelve sensor set in the data character mode enters data when the third right preferred pound “#” sensor of the second set of three sensors is activated twice.

The first set of nine sensors exits the data character mode and re-enters the ten sensor number mode when the third right preferred pound “#” sensor of the second set of three sensors is activated and combined with the activation of the second middle sensor of the second set of three sensors.

The twelve sensor set in the number mode exits the number mode and enters a voice recognition mode when the first left preferred asterisk “*” sensor of the second set of three sensors is activated. The twelve sensor set in the number mode exits the number mode and enters a predictive text mode when the first left preferred asterisk “*” sensor of the second set of three sensors is activated. The twelve sensor set in the number mode exits the number mode and enters a language mode when the first left preferred asterisk “*” sensor of the second set of three sensors is activated.

The twelve sensor set produces audio data through a speaker corresponding to the data entered on the twelve sensor set when at least one sensor of the twelve sensor set is activated. The twelve sensor set produces visual data through a visual display corresponding to the data entered on the twelve sensor set when at least one sensor of the twelve sensors is activated. The twelve sensor set produces tactile data through a tactile display corresponding to the data entered on the twelve sensor set when at least one sensor of the twelve sensors is activated.

The twelve sensor set produces a twelve bit binary code when at least one sensor of the twelve sensors is activated.

The twelve sensor set produces a nine bit binary code combined with a three bit binary code when at least one sensor of the first set of nine sensors is activated or when at least one sensor of the second set of three sensors is activated.

The twelve sensor set produces a nine bit binary code combined with a throe bit binary code when at least one sensor of the first set of nine sensors is activated and combined with the activation of at least one sensor of the second set of three sensors.

This method of using twelve sensors for data representation or data entry produces numbers, all lower-case data, all upper-case data, a space, all punctuation, symbols and control found on a standard keyboard.

A latitude of modifications change, and/or substitution is intended in the foregoing disclosure, and in some instances, some features of the preferred embodiment will be employed without a corresponding use of one or more of the other features. Accordingly, it is appropriate that the appended claims be construed broadly and in a manner consistent with the spirit and scope of the invention herein.

A portion of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyrights whatsoever.

I claim:

1. A method of producing data using a twelve sensor set, wherein said twelve sensor set includes:
a first set of nine sensors, numbered one “1” through nine “9”, with each said sensor including three data characters, and
a second set of three sensors comprising a first left sensor, a second middle sensor numbered zero “0” and a third right sensor;
said first set of nine numbered sensors and said zero sensor of said second set of three sensors define ten numbered sensors;
comprising the steps of:
a) said twelve sensor set produces numeric data in a number mode, when one of said ten numbered sensors is activated;
b) said twelve sensor set exits said ten sensor number mode and enters a data character mode on said first set of nine sensors when said first left sensor of said second set of three sensors is activated; and
c) said first set of nine sensors exits said data character mode and re-enters said ten sensor number mode when said third right sensor of said second set of three sensors is activated.

2. A method of producing data using said twelve sensor set of claim 1. wherein:
said twelve sensor set in said number mode produces a dot/period/decimal point when said first left sensor of said second set of three sensors is activated and combined with the activation of said second middle sensor of said second set of three sensors.

3. A method of producing data using said twelve sensor set of claim 1. wherein:
said twelve sensor set in said number mode produces a dash/hyphen/minus sign when said first left sensor of said second set of three sensors is activated and combined with the activation of said third right sensor of said second set of three sensors.

4. A method of producing data using said twelve sensor set of claim 1. wherein:
said twelve sensor set in said number mode deletes the previously entered number when said third right sensor of said second set of three sensors is activated twice.

5. A method of producing data using said twelve sensor set of claim 1. wherein:
said twelve sensor set in said number mode deletes the previously entered numeric data string when said third right sensor of said second set of three sensors is activated three times.

6. A method of producing data using said twelve sensor set of claim 1. wherein:
said twelve sensor set in said number mode enters data when said third right sensor of said second set of three sensors is activated and combined with the activation of said second middle sensor of said second set of three sensors.

7. A method of producing data using said twelve sensor set of claim 1 wherein:
said twelve sensor set produces a stored data string when one said sensor of said twelve sensors is activated for a preset length of time.

8. A method of producing data using said twelve sensor set of claim 1. wherein:
said twelve sensor set produces a stored data string when one said sensor of said twelve sensors is activated and followed by the secondary activation of said sensor of said twelve sensors for a preset length of time.

9. A method of producing data using said twelve sensor set of claim 1. wherein:
said twelve sensor set produces a stored data string when one said sensor of said twelve sensors is activated and combined with the activation of one said sensor of said twelve sensors for a preset length of time.

10. A method of producing data using said twelve sensor set of claim 1. wherein:
said twelve sensor set exits said number mode and enters a cursor mode on said first set of nine sensors, when said third right sensor of said second set of three sensors is activated;
followed by the activation of:
a top row middle sensor for moving up in a data field,
a right row middle sensor for moving right in a data field,
a bottom row middle sensor for moving down in a data field,
a left row middle sensor for moving left in a data field,
a top row left sensor for returning home in a data field,
a bottom row left sensor for moving back in a data field,
a top row right sensor for moving forward in a data field,
a bottom row right sensor for moving to the end of a data field, or
a middle row middle sensor for entering a data field; and
said twelve sensor set exits said cursor mode on said first set of nine sensors and re-enters said ten sensor number mode when said third right sensor of said second set of three sensors is activated, and
said twelve sensor set exits said cursor mode on said first set of nine sensors and enters said ten sensor data character mode when said first left sensor of said second set of three sensors is activated.

11. A method of producing data using said twelve sensor set of claim 1. wherein:
said twelve sensor set exits said number mode and enters a cursor mode on are said first set of nine sensors, when said third right sensor of said second set of three sensors is activated;
followed by the activation of:
said “2” sensor for moving up in a data field,
said “6” sensor for moving right in a data field,
said “8” sensor for moving down in a data field,
said “4” sensor for moving left in a data field,
said “1” sensor for returning home in a data field,
said “7” sensor for moving back in a data field,
said “3” sensor for moving forward in a data field,
said “9” sensor for moving to the end of a data field, or
said “5” sensor for entering a data field; and
said twelve sensor set exits said cursor mode on said first set of nine sensors and re-enters said ten sensor number mode when said third right sensor of said second set of three sensors is activated, and
said twelve sensor set exits said cursor mode on said first set of nine sensors and enters said ten sensor data character mode when said first left sensor of said second set of three sensors is activated.

12. A method of producing data using said twelve sensor set of claim 1. wherein:
said twelve sensor set exits said ten sensor number mode and enters a second ten sensor number mode when said third right sensor of said second set of three sensors is activated at least once.

13. A method of producing data using said twelve sensor set of claim 1. wherein:
said twelve sensor set exits said ten sensor number mode and enters a second ten sensor number mode when said third right sensor of said second set of three sensors is activated; and
activation of a first said numbered sensor combined with the activation of a second said numbered sensor enters a location mode; and
activation of a third said numbered sensor produces one of ten location mode exchanges.

14. A method of producing data using said twelve sensor set of claim 1. wherein:
said twelve sensor set in said data character mode produces one of three data characters when one said sensor of said first set of nine sensors is activated.

15. A method of producing data using said twelve sensor set of claim 1. wherein:
said twelve sensor set exits said ten sensor number mode and enters a lower-case data character mode on said first set of nine sensors when said first left sensor of said second set of three sensors is activated at least once.

16. A method of producing data using said twelve sensor set of claim 1. wherein:
said twelve sensor set exits said ten sensor number mode and enters a upper-case data character mode on said first set of nine sensors when said first left sensor of said second set of three sensors is activated at least once.

17. A method of producing data using said twelve sensor set of claim 1. wherein:
said twelve sensor set in said data character mode produces one of three data characters when one said sensor of said first set of nine sensors is activated; and
combined with the activation of:
said first left sensor of said second set of three sensors for producing a first left data character;
said second middle sensor of said second set of three sensors for producing a second middle data character; or
said third right sensor of said second set of three sensors for producing a third right data character.

18. A method of producing data using said twelve sensor set of claim 1. wherein:
said twelve sensor set exits said ten sensor number mode and enters a data character mode when said first left sensor of said second set of three sensors is activated twice.

19. A method of producing data using said twelve sensor set of claim 1. wherein:
said twelve sensor set exits said ten sensor number mode and enters a shiftable data character mode when said first left sensor of said second set of three sensors is activated twice.

20. A method of producing data using said twelve sensor set of claim 1. wherein:
said twelve sensor set in said data character mode produces a second middle data character when one said sensor of said first set of nine sensors is activated; or
combined with the activation of:
said first left sensor of said second set of three sensors for producing a first left data character; or
said third right sensor of said second set of three sensors for producing a third right data character.

21. A method of producing data using said twelve sensor set of claim 1. wherein:
said twelve sensor set in said data character mode produces the most frequently used data character when one said sensor of said first set of nine sensors is activated; or
is combined with the activation of:
said first left sensor of said second set of three sensors for producing a first left data character;
said second middle sensor of said second set of three sensors for producing a second middle data character; or
said third right sensor of said second set of three sensors for producing a third right data character.

22. A method of producing data using said twelve sensor set of claim 1. wherein:
said twelve sensor set exits said ten sensor number mode and enters a data character mode when said first left sensor of said second set of three sensors is activated three times.

23. A method of producing data using said twelve sensor set of claim 1. wherein:
said twelve sensor set exits said ten sensor number mode and enters a shiftable data character mode when said first left sensor of said second set of three sensors is activated three times.

24. A method of producing data using said twelve sensor set of claim 1. wherein:
said twelve sensor set in said data character mode produces a data character when one said sensor of said first set of nine sensors is activated; and
combined with the activation of:
said first left sensor of said second set of three sensors for producing a first left lower-case data character;
said second middle sensor of said second set of three sensors for producing a second middle lower-case data character;
said third right sensor of said second set of three sensors for producing a third right lower-case data character;
said first left sensor of said second set of three sensors twice for producing a first left upper-case data character;
said second middle sensor of said second set of three sensors twice for producing a second middle upper-case data character; or
said third right sensor of said second set of three sensors twice for producing a third right upper-case data character.

25. A method of producing data using said twelve sensor set of claim 1. wherein:
said twelve sensor set in said data character mode produces a data character when one said sensor of said first set of nine sensors is activated twice; and
combined with the activation of:
said first left sensor of said second set of three sensors for producing said data character;
said second middle sensor of said second set of three sensors for producing said data character;
said third right sensor of said second set of three sensors for producing said data character;
said first left sensor of said second set of three sensors twice for producing an upper-case data character;
said second middle sensor of said second set of three sensors twice for producing an upper-case data character; or
said third right sensor of said second set of three sensors twice for producing an upper-case data character.

26. A method of producing data using said twelve sensor set of claim 1. wherein:
said twelve sensor set in said data character mode produces a data character when one said sensor of said first set of nine sensors is activated and combined with the activation of one said sensor of said first set of nine sensors; and
combined with the activation of:
said first left sensor of said second set of three sensors for producing said data character;
said second middle sensor of said second set of three sensors for producing said data character;
said third right sensor of said second set of three sensors for producing said data character;
said first left sensor of said second set of three sensors twice for producing an upper-case data character;
said second middle sensor of said second set of three sensors twice for producing an upper-case data character; or
said third right sensor of said second set of three sensors twice for producing an upper-case data character.

27. A method of producing data using said twelve sensor set of claim 1. wherein:
said twelve sensor set in said data character mode produces a space when one said sensor of said first set of nine sensors is activated.

28. A method of producing data using said twelve sensor set of claim 1. wherein:
said twelve sensor set in said data character mode produces a space when said second middle sensor of said second set of three sensors is activated twice.

29. A method of producing data using said twelve sensor set of claim 1. wherein:
said twelve sensor set in said data character mode produces a tab function when said second middle sensor of said second set of three sensors is activated three times.

30. A method of producing data using said twelve sensor set of claim 1. wherein:
said twelve sensor set in said data character mode produces a dot/period/decimal point when said first left sensor of said second set of three sensors is activated and combined with the activation of said second middle sensor of said second set of three sensors.

31. A method of producing data using said twelve sensor set of claim 1. wherein:
said twelve sensor set in said data character mode produces a dash/hyphen/minus sign when one said sensor of said first set of nine sensors is activated and
combined with the activation of said second middle sensor of said second set of three sensors.

32. A method of producing data using said twelve sensor set of claim 1. wherein:
said twelve sensor set in said data character mode deletes the previously entered data character when said first left sensor of said second set of three sensors is activated twice.

33. A method of producing data using said twelve sensor set of claim 1. wherein:
said twelve sensor set in said data character mode deletes the previously entered data character string when said first left sensor of said second set of three sensors is activated three times.

34. A method of producing data using said twelve sensor set of claim 1. wherein:
said twelve sensor set in said data character mode enters a punctuation mode when said first left sensor of said second set of three sensors is activated and combined with the activation of said third right sensor of said second set of three sensors.

35. A method of producing data using said twelve sensor set of claim 1. wherein:
said twelve sensor set in said data character mode enters a second punctuation mode when said first left sensor of said second set of three sensors is activated and combined with the activation of said third right sensor of said second set of three sensors twice.

36. A method of producing data using said twelve sensor set of claim 1. wherein:
said twelve sensor set in said data character mode enters a third punctuation mode when said first left sensor of said second set of three sensors is activated and combined with the activation of said third right sensor of said second set of three sensors three times.

37. A method of producing data using said twelve sensor set of claim 1. wherein:
said twelve sensor set in said data character mode enters data when said third right sensor of said second set of three sensors is activated twice.

38. A method of producing data using said twelve sensor set of claim 1. wherein:
said first set of nine sensors exits said data character mode and re-enters said ten sensor number mode when said third right sensor of said second set of three sensors is activated and combined with the activation of said second middle sensor of said second set of three sensors.

39. A method of producing data using said twelve sensor set of claim 1. wherein:
said twelve sensor set in said number mode exits said number mode and enters a voice recognition mode when said first left sensor of said second set of three sensors is activated.

40. A method of producing data using said twelve sensor set of claim 1. wherein:
said twelve sensor set in said number mode exits said number mode and enters a predictive text mode when said first left sensor of said second set of three sensors is activated.

41. A method of producing data using said twelve sensor set of claim 1. wherein:
said twelve sensor set in said number mode exits said number mode and enters a language mode when said first left sensor of said second set of three sensors is activated.

42. A method of producing data using said twelve sensor set of claim 1. wherein:
said twelve sensor set produces audio data through a speaker when at least one said sensor of said twelve sensor set is activated.

43. A method of producing data using said twelve sensor set of claim 1. wherein:
said twelve sensor set produces visual data through a visual display when at least one said sensor of said twelve sensors is activated.

44. A method of producing data using said twelve sensor set of claim 1. wherein:
said twelve sensor set produces tactile data through a tactile display when at least one said sensor of said twelve sensors is activated.

45. A method of producing data using a twelve sensor set wherein:
said twelve sensor set produces a nine bit binary code combined with a three bit binary code when at least one sensor of a first set of nine sensors is activated or when at least one sensor of a second set of three sensors is activated.

46. A method of producing data using a twelve sensor set wherein:
said twelve sensor set produces a nine bit binary code combined with a three bit binary code when at least one sensor of a first set of nine sensors is activated and combined with the activation of at least one sensor of a second set of three sensors.
